(19) United States
(12) Patent Application Publication
(10) Pub. No.: US 2007/0275624 A1
(43) Pub. Date: Nov. 29, 2007

(54) Method of the manufacturing an organic EL display

(75) Inventors: Koji Kawaguchi, Nagano (JP); Toshio Hama, Nagano (JP); Yutaka Terao, Nagano (JP)

Correspondence Address: RABIN & Berdo, PC, 1101 14TH STREET, NW, SUITE 500, WASHINGTON, DC, 20005, US

(73) Assignee: FUJI ELECTRIC HOLDINGS CO., LTD., Tokyo (JP)

(21) Appl. No.: 11/638,705

(22) Filed: Dec. 14, 2006

(30) Foreign Application Priority Data
Dec. 14, 2005 (JP) JP 2005-360975
Jul. 26, 2006 (JP) JP 2006-203232

(51) Int. Cl. H01J 9/24

(52) U.S. Cl. 445/24

(57) ABSTRACT

Manufacturing an organic EL display by: forming n types of color filter layers on a transparent substrate; forming a dye layer containing (n−1) types of color conversion dyes by a dry process; forming an organic EL device on the dye layer; and exposing the dye layer to dye-decomposing light from the side of the transparent substrate to form an m-th type color conversion layer at a position corresponding to an m-th type color filter layer; where n represents an integer from 2 to 6; m represents an integer from 1 to (n−1); each of the color filter layers transmits light in a different wavelength region; m-th type color conversion dye is decomposed by light cut by the m-th type color filter layer; and the m-th type color conversion layer emits light transmitted by the m-th type color filter layer after wavelength distribution conversion.

### CROSS-REFERENCE TO RELATED APPLICATION

This application is based on, and claims priority to, Japanese Patent Application No. 2005-360975, filed on Dec. 14, 2005, the contents of which are incorporated herein by reference.

### BACKGROUND OF THE INVENTION

1. Field of the Invention

The present invention relates to a method of manufacturing an organic EL display capable of multi color display. The organic EL display can be applied, for example, to image sensors, personal computers, word processors, televisions, facsimiles, audio equipment, video recorders, car navigation, electronic calculators, telephones, mobile terminals, and industrial instruments.

2. Description of the Related Art

For multi color or full color display, color conversion systems have recently been studied that use a filter containing color conversion dye that absorbs light in the near-ultraviolet, blue, blue-green, or white light spectra, changes the wavelength distribution of the light, and emits light in the visible light range (see JP 08-279394 A and JP 08-286033 A). Since the light emitted by a light source is not limited to white in this color conversion system, the light source can be more freely selected. For example, an organic EL light emitting device emitting blue colored light can be used to obtain green and red colored light after changing the wavelength distribution. Thus, the possibility has been studied of constructing a display that allows utilizing a light source of higher efficiency, and provides a full color, self-light emitting display using only a weak light energy line in the range of near-ultraviolet to visible light (see JP 09-080434 A).

Major practical problems in color displays include, in addition to definite color display performance and long-term stability, reproducibility of color and provision of a color conversion filter exhibiting high color conversion efficiency. However, if the concentration of the color conversion dye is increased to increase color conversion efficiency, the efficiency actually decreases due to so-called concentration quenching, and decomposition of the color conversion dye occurs with the passage of time. To cope with this problem in the prior art, the thickness of a color conversion layer containing the color conversion dye was increased to obtain a desired color conversion efficiency. To avoid the concentration quenching and decomposition of color conversion dyes, studies have been made in which a bulky substituent is introduced into a core of the color conversion dye (see JP 11-279426 A, JP 2000-044824 A, and JP 2001-164245 A). Mixing of a quencher has also been studied for preventing the color conversion dye from decomposing (see JP 2002-231450 A). Another means has been studied, that is, a color conversion dye film formed by a dry process such as evaporation (see JP 03-152897 A).

To obtain a high definition multi-color or full color display employing a color conversion system, the patterning of the color conversion layer must be very clearly defined. However, in a case of patterning having a width smaller than a film thickness, for example, problems of reproducibility of the pattern and distortion of the pattern in the subsequent processes may arise. In addition, patterning by normal photolithography requires an applying step, an exposure step accompanying mask alignment, and a development step for every color conversion layer for each respective color. A full color display needs at least red, green, and blue color conversion layers. So, a procedure of producing the full color display requires multiple steps and is rather complicated. When a color conversion dye film formed by a dry process is used for a color conversion layer, patterning can be carried out by means of a mask evaporation method. The mask evaporation method, however, requires high precision alignment in a vacuum. That is a highly difficult process, and limitations exist in the degree of definition and the substrate dimensions that can be employed.

### SUMMARY OF THE INVENTION

It is therefore an object of the present invention to provide a method of manufacturing an organic EL display in which manufacturing processes are simplified and high definition patterning is performed.

A method of manufacturing an organic EL display in a first aspect of the present invention comprises steps of: forming n types of color filter layers on a transparent substrate; forming a dye layer containing (n−1) types of color conversion dyes on the n types of color filter layers by means of a dry process; forming an organic EL device having a plurality of independent light emitting elements on the dye layer, the organic EL device including at least a first electrode, a second electrode, and an organic EL layer disposed between the first and second electrodes; and exposing the dye layer to dye-decomposing light through the transparent substrate and the color filter layers to form an m-th type color conversion layer at a position corresponding to an m-th type color filter layer; wherein n represents an integer from 2 to 6; m represents an integer from 1 to (n−1); each of the n types of color filter layers transmits light in a distinct wavelength region different from each other; the m-th type color conversion dye is decomposed by light that is cut by the m-th type color filter layer; and the m-th type color conversion layer emits light that is transmitted by the m-th type color filter layer, after wavelength distribution conversion.

The exposure to dye-decomposing light can be conducted plural times and a wavelength component that decomposes the m-th type color conversion dye is included in at least one of the dye-decomposing lights used in the plural instances of exposure. A bias voltage can be applied to the plurality of independent light emitting elements in the step of exposure to the dye-decomposing light. The bias voltage can be applied to some or all of the plurality of independent light emitting elements, and can be either a forward bias voltage or a reverse bias voltage. The forward bias voltage and the reverse bias voltage can be applied alternately. The method can further comprise a step of monitoring an emission spectrum from the organic EL display during application of a forward bias voltage to the plurality of independent light emitting elements and controlling the quantity of the dye-decomposing light according to the emission spectrum. The transparent substrate can be heated in the step of exposing to the dye-decomposing light.

A method of manufacturing an organic EL display in a second aspect of the present invention comprises steps of: forming n types of color filter layers on a transparent substrate; forming an organic EL device having a plurality of independent light emitting elements on the n types of color filter layers, the organic EL device including at least a first electrode, a second electrode, and an organic EL layer disposed between the first and second electrodes; forming a dye layer containing (n−1) types of color conversion dyes on the organic EL device by means of a dry process; forming a reflective layer on the dye layer; and exposing the dye layer to dye-decomposing light through the transparent substrate and the color filter layers to form an m-th type color conversion layer at a position corresponding to an m-th type color filter layer; wherein n represents an integer from 2 to 6; m represents an integer from 1 to (n−1); each of the n types of color filter layers transmits light in a distinct wavelength region different from each other; the m-th type color conversion dye is decomposed by light that is cut by the m-th type color filter layer; and the m-th type color conversion layer emits light that is transmitted by the m-th type color filter layer, after wavelength distribution conversion.

The exposure to the dye-decomposing light can be conducted plural times and a wavelength component that decomposes the m-th type color conversion dye is included in at least one of the dye-decomposing lights used in the plural instances of exposure. A bias voltage can be applied to the plurality of independent light emitting elements in the step of exposing to the dye-decomposing light. The bias voltage can be applied to some or all of the plurality of independent light emitting elements, and can be either a forward bias voltage or a reverse bias voltage. The forward bias voltage and the reverse bias voltage can be applied alternately. The method can further comprise a step of monitoring an emission spectrum from the organic EL display during application of a forward bias voltage to the plurality of independent light emitting elements and controlling quantity of the dye-decomposing light according to the emission spectrum. The transparent substrate can be heated in the step of exposing to the dye-decomposing light.

A method of manufacturing an organic EL display in a third aspect of the present invention comprises steps of: forming n types of color filter layers on a transparent substrate; forming an organic EL device having a plurality of independent light emitting elements on the n types of color filter layers by means of a dry process, the organic EL device including at least a first electrode, a second electrode, and an organic-EL layer including at least an organic light emitting layer and a carrier-transporting dye layer disposed between the first and second electrodes, the carrier-transporting dye layer including at least (n−1) types of color conversion dyes; and exposing the carrier-transporting dye layer to dye-decomposing light through the transparent substrate and the color filter layers to form an m-th type carrier-transporting color conversion layer at a position corresponding to an m-th type color filter layer; wherein n represents an integer from 2 to 6; m represents an integer from 1 to (n−1); each of the n types of color filter layers transmits light in a distinct wavelength region different from, each other; the m-th type color conversion dye is decomposed by light that is cut by the m-th type color filter layer; and the m-th type carrier-transporting color conversion layer emits light that is transmitted by the m-th type color filter layer, after wavelength distribution conversion.

The exposure to the dye-decomposing light can be conducted plural times and a wavelength component that decomposes the m-th type color conversion dye is included in at least one of the dye-decomposing light used in the plural instances of exposure. A bias voltage can be applied to the plurality of independent light emitting elements in the step of exposing to the dye-decomposing light. The bias voltage can be applied to some or all of the plurality of independent light emitting elements, and can be either a forward bias voltage or a reverse bias voltage. The forward bias voltage and the reverse bias voltage can be alternately applied. The method can further comprise a step of monitoring an emission spectrum from the organic EL display during application of a forward bias voltage to the plurality of independent light emitting elements and controlling quantity of the dye-decomposing light according to the emission spectrum. The transparent substrate can be heated in the step of exposing to the dye-decomposing light.

A method of manufacturing an organic EL display in a fourth aspect of the present invention comprises steps of: forming n types of color filter layers on a transparent substrate; forming a dye layer containing (n−1) types of color conversion dyes dispersed in a resin on the n types of color filter layers; forming an organic EL device having a plurality of independent light emitting elements on the dye layer, the organic EL device including at least a first electrode, a second electrode, and an organic EL layer disposed between the first and second electrodes; and exposing the dye layer to dye-decomposing light through the transparent substrate and the color filter layers to form an m-th type color conversion layer at a position corresponding to an m-th type color filter layer; wherein n represents an integer from 2 to 6; m represents an integer from 1 to (n−1); each of the n types of color filter layers transmits light in a distinct wavelength region different from each other; the m-th type color conversion dye is decomposed by light that is cut by the m-th type color filter layer; and the m-th type color conversion layer emits light that is transmitted by the m-th type color filter layer, after wavelength distribution conversion.

The exposure to the dye-decomposing light can be conducted plural times and a wavelength component that decomposes the m-th type color conversion dye is included in at least one of the dye-decomposing light used in the plural instances of exposure. A bias voltage can be applied to the plurality of independent light emitting elements in the step of exposing to the dye-decomposing light. The bias voltage can be applied to some or all of the plurality of independent light emitting elements, and can be either a forward bias voltage or a reverse bias voltage. The forward bias voltage and the reverse bias voltage can be alternately applied. The method can further comprise a step of monitoring an emission spectrum from the organic EL display during application of a forward bias voltage to the plurality of independent light emitting elements and controlling quantity of the dye-decomposing light according to the emission spectrum. The transparent substrate can be heated in the step of exposing to the dye-decomposing light.

A method of manufacturing an organic EL display in a fifth aspect of the present invention comprises steps of: forming n types of color filter layers on a transparent substrate; forming an organic EL device having a plurality of independent light emitting elements on a second substrate, the organic EL device including at least a first electrode, a second electrode, and an organic EL layer disposed between the first and second electrodes; forming a dye layer containing (n−1) types of color conversion dyes on the organic EL device; combining the transparent substrate and the second substrate together such that the color filter layers are opposing the dye layer; and exposing the dye layer to dye-decomposing light through the transparent substrate and the color filter layers to form an m-th type color conversion layer at a position corresponding to an m-th type color filter layer; wherein n represents an integer from 2 to 6; m represents an integer from 1 to (n−1); each of the n types of color filter layers transmits light in a distinct wavelength region different from each other; the m-th type color conversion dye is decomposed by light that is cut by the m-th type color filter layer; and the m-th type color conversion layer emits light that is transmitted by the m-th type color filter layer, after wavelength distribution conversion.

The exposure to the dye-decomposing light can be conducted plural times and a wavelength component that decomposes the m-th type color conversion dye is included in at least one of the dye-decomposing light used in the plural instances of exposure. A bias voltage can be applied to the plurality of independent light emitting elements in the step of exposing to the dye-decomposing light. The bias voltage can be applied to some or all of the plurality of independent light emitting elements, and can be either a forward bias voltage or a reverse bias voltage. The method can further comprise a step of monitoring an emission spectrum from the organic EL display during application of a forward bias voltage to the plurality of independent light emitting elements and controlling quantity of the dye-decomposing light according to the emission spectrum. At least one of the transparent substrate and the second substrate can be heated in the step of exposing to the dye-decomposing light.

A manufacturing method according to the invention constituted as described above allows forming a color conversion layer with high definition owing to the self-alignment secured by the color filter layers that work as a mask. A color conversion filter with high color conversion efficiency can be achieved by combining the color filter layer and the color conversion layer. Such a method according to a preferred embodiment of the invention eliminates the need for patterning the color conversion layer by means of photolithography or mask evaporation, thereby shortening the manufacturing steps. Since partial regions of a monolithically formed dye layer are converted to the color conversion layers, the color conversion layers and surrounding layers (a transparent layer, for example) can be formed as a monolithic single film. Therefore, distortion of the color conversion layer is avoided even in the case of forming a narrower color conversion layer than the film thickness. Consequently, displays for use in micro displays (for example, a viewing finder in a video camera) can be manufactured by a method according to a preferred embodiment of the invention.

### BRIEF DESCRIPTION OF THE DRAWINGS

FIG. 1A through FIG. 1C show schematically the steps in a method of manufacturing an organic EL display according to a first aspect of the invention.

FIG. 2A through FIG. 2C show schematically the steps in a method of manufacturing an organic EL display according to a second aspect of the invention.

FIG. 3A through FIG. 3C show schematically the steps in a method of manufacturing an organic EL display according to a third aspect of the invention.

FIG. 4A through FIG. 4C show a schematic structure of an organic EL layer in the steps in a method of manufacturing an organic EL display according to a third aspect of the invention.

FIG. 5A through FIG. 5C show schematically the steps in a method of manufacturing an organic EL display according to a fourth aspect of the invention.

FIG. 6A and FIG. 6B show laminates for constituting an organic EL display according to a fifth aspect of the invention, in which FIG. 6A shows schematically a laminate of transparent substrate/color filter layer, and FIG. 6B, a laminate of second substrate/organic EL device/dye layer.

FIG. 7A and FIG. 7B show schematically the steps in a method of manufacturing an organic EL display according to a fifth aspect of the invention.

### DETAILED DESCRIPTION OF THE INVENTION

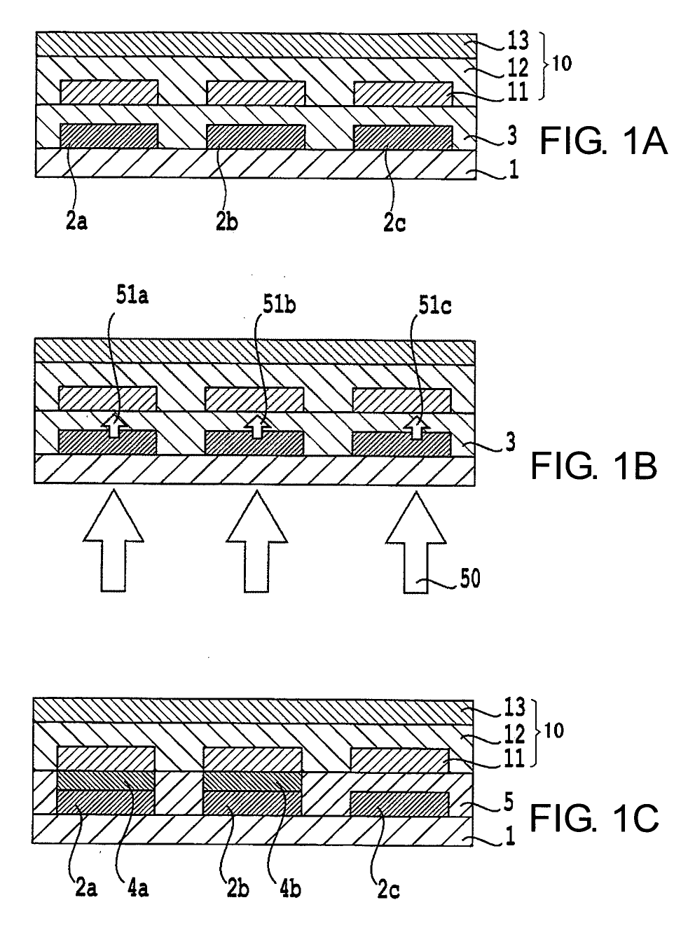

A method of manufacturing an organic EL display in the first aspect of the present invention comprises steps of: forming n types of color filter layers on a transparent substrate; forming a dye layer containing (n−1) types of color conversion dyes on the n types of color filter layers; forming an organic EL device having a plurality of independent light emitting elements on the dye layer, the organic EL device including at least a first electrode, a second electrode, and an organic EL layer disposed between the first and second electrodes; and exposing the dye layer to dye-decomposing light through the transparent substrate and the color filter layers to form an m-th type color conversion layer at a position corresponding to an m-th type color filter layer; wherein n represents an integer from 2 to 6; m represents an integer from 1 to (n−1); each of the n types of color filter layers transmits light in a distinct wavelength region different from each other; the m-th type color conversion dye is decomposed by light that is cut by the m-th type color filter layer; and the m-th type color conversion layer emits light that is transmitted by the m-th type color filter layer, after wavelength distribution conversion. FIG. 1A-1C show an exemplary structure of an organic EL display in the case of three color filter layers and two types of color conversion dyes (n=3). In the structure of FIG. 1A-1C, a first electrode is the transparent electrode 11 and a second electrode is the reflective electrode 13.

The transparent substrate 1 is necessarily transparent to the visible light (wavelength range from 400 nm to 700 nm), preferably to the light converted by the color conversion layers. The transparent substrate 1 must withstand the conditions (solvent, temperature and so on) in the process of forming the color filter layers and upper layers, and other layers that are formed as needed (described hereinafter). The substrate is desired to exhibit good dimensional stability. Preferred materials for the transparent substrate 1 include glass and resins such as poly(ethylene terephthalate) and poly(methyl methacrylate). Particularly favorable are borosilicate glass and blue plate glass.

The color filter layer transmits only light in the desired wavelength region. The color filter layer, in the completed color conversion filter, cuts off the light from the light source that is not converted wavelength distribution in the color conversion layer, and effectively improves color purity of the light that is converted wavelength distribution in the color conversion layer. From 2 to 6 types of color filter layers can be used in the invention. The color filter layers in the specification of the present invention are referred to as first, second, . . . and n-th color filter layer according to the sequence from longest to shortest wavelength of the wavelength region of the light for transmitting through the color filter layer. The invention favorably uses, as shown in FIG. 1A-1C, first color filter layer 2a (red color), second color filter layer 2b (green color), and third color filter layer 2c (blue color) in the sequence from longer to shorter wavelength. The color filter layers in this aspect of the invention function as a mask in the process of patterning the dye layer to form color conversion layers in the post-step of color conversion layer formation.

The color filter layers 2a, 2b, and 2c contain a color conversion dye and a photosensitive resin. A preferred color conversion dye is selected from pigments that exhibit sufficient light stability. Preferred photosensitive resins include: (1) compositions composed of acrylic polyfunctional monomers and oligomers that contain acroyl groups or methacroyl groups, and a photo-polymerization initiator, (2) compositions comprised of poly(vinyl cinnamate) and photo sensitizer, (3) compositions composed of direct chain or cyclic olefin and bisazide (nitrene is generated to crosslink the olefin). A color filter layer can be formed using, for example, a commercially available color filter material for liquid crystal devices (Color Mosaic produced by FUJIFILM Electronic Materials Co., Ltd, for example).

The color filter layers 2a, 2b, and 2c have a thickness in the range of 1 to 2.5 μm, preferably in the range of 1 to 1.5 μm, depending on the contents of the color conversion dye. The film thickness in this range allows high definition patterning, and the color filters function as a mask in the color conversion layer formation process and gives a transmission spectrum that is sufficient for the completed filter.

The dye layer 3 contains (n−1) types of color conversion dyes and formed by means of a dry process. The color conversion dyes in this aspect of the invention conduct wavelength distribution conversion to the incident light, and emit light in the wavelength region that transmits the color filter layers. In the case of n=3 as shown in FIG. 1A-1C, the dye layer 3 contains a first color conversion dye and a second color conversion dye. The first color conversion dye conducts wavelength distribution conversion to the light in the blue to blue-green color and emits light in the wavelength region that transmits through the first color filter layer 2a (the light being red color light), while the second color conversion dye emits light in the wavelength region that transmits through the second color filter layer 2b (the light being green color light). The first color conversion dye is not decomposed by the light in the wavelength region that transmits through the first color filter layer 2a, and is decomposed by the light in the wavelength region that does not transmit through the first color filter layer 2a (the light normally being in the shorter wavelength region). The second color conversion dye is not decomposed by the light in the wavelength region that transmits through the second color filter layer 2b, and is decomposed by the light in the wavelength region that does not transmit through the second color filter layer 2b (the light normally being in the shorter wavelength region). In general, an m-th type color conversion dye (m is an integer from 1 to n−1) conducts wavelength distribution conversion to the light in blue to blue-green color and emits light in the wavelength region that transmits through an m-th type color filter layer; the m-th type color conversion dye is not decomposed by the light in the wavelength region that transmits through the m-th type color filter layer, and is decomposed by the light in the wavelength region that does not transmit through the m-th type color filter layer. The m-th type color conversion dye is normally decomposed by the light in the wavelength region shorter than the wavelength region of the light that transmits the m-th type color filter layer. It is important for every color conversion dye not to generate a colored decomposition product in the photochemical decomposition reaction. The decomposition products of the color conversion dye are strictly required to exhibit no absorption in the wavelength region that is obtained from wavelength distribution conversion by the color conversion dye. If the light in this wavelength region is absorbed, efficiency in the color conversion decreases. Even if the light in this wavelength region is not absorbed, any colored decomposition products is yet undesirable because it gives unwanted coloring to the display.

A color conversion dye that absorbs light in blue to blue-green color region and emits light in red color region (the first color conversion dye in the example of FIG. 1A-1C) can be selected from rhodamine dyestuffs such as rhodamine B, rhodamine 6G, rhodamine 3B, rhodamine 101, rhodamine 110, sulforhodamine, basic violet 11, and basic red 2; cyanine dyestuffs such as 4-dicyanomethylene-2-methyl-6-(p-dimethylaminostyryl)-4H-pyrane (DCM-1:I), DCM-2 (II), and DCJTB (III); pyridine dyestuffs such as 1-ethyl-2-[4-(p-dimethylaminophenyl)-1,3-butadienyl]-pyridium perchlorate (pyridine 1); oxazine dyestuffs; and dyestuffs for red color light emitting materials such as 4,4-difluoro-1,3,5,7-tetraphenyl-4-bora-3a,4a-diaza-s-indacene (IV) and Nile Red (V).

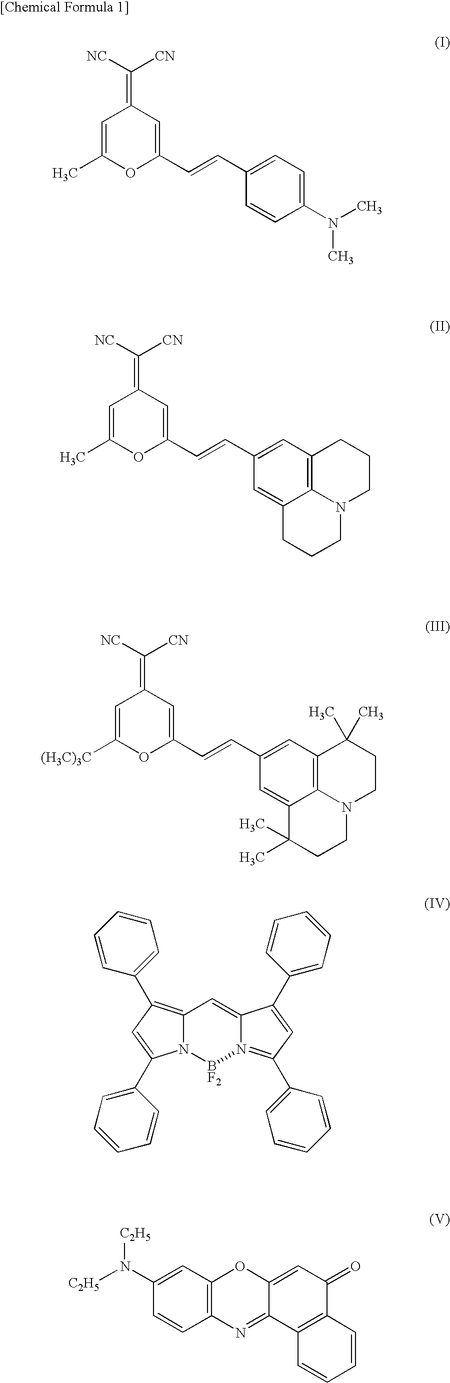

A color conversion dye that absorbs light in blue to blue-green color region and emits light in green color region (the second color conversion dye in the example of FIG. 1A-1C) can be selected from coumarin dyestuffs such as 3-(2′-benzothiazolyl)-7-diethylamino-coumarin (coumarin 6), 3-(2′-benzoimidazolyl)-7-diethylamino-coumarin (coumarin 7), 3-(2′-N-methylbenzoimidazolyl)-7-diethylamino-coumarin (coumarin 30), 2,3,5,6-1H,4H-tetrahydro-8-trifluoromethyl quinolidine (9,9a,1-gh) coumarin (coumarin 153), a dyestuff in a class of coumarin dyestuff of basic yellow 51, and naphthalimide dyestuffs such as solvent yellow 11 and solvent yellow 116.

The dye layer 3 in this aspect of the invention is formed by means of a dry process. Specifically, the dye layer 3 can be formed by evaporating (n−1) types of color conversion dyes on the color filter layers. Other materials can be co-evaporated with the color conversion dye in order to improve properties such as adhesivity of the evaporated dye layer 3 or the color conversion layer that is to be transformed from the dye layer. The materials that can be co-evaporated with the color conversion dye include for example, aluminum complexes such as tris(8-hydroxyquinolinato) aluminum (Alq₃) and tris(4-methyl-8-hydroxyquinolinato) aluminum (Almq3); 4,4′-bis(2,2-diphenylvinyl)biphenyl (DPVBi); and 2,5-bis-(5-tert-butyl-2-benzoxazoril)thiophene. The dye layer of this aspect of the invention is desirably composed of (n−1) types of color conversion dyes alone, or (n−1) types of color conversion dyes and one or more types of the aforementioned co-evaporation materials.

The dye layer 3 is formed covering the color filter layers to a thickness in the range of 100 nm to 1 μm, more preferably in the range of 150 nm to 600 nm. The dye layer 3 is formed by means of an evaporation method, a dry process, and transformed into a color conversion layer in a dry process as described later. Therefore, moisture, which may cause degradation of the organic EL device, cannot be contained.

Transparent electrode 11 is desired to have a transmittance at least 50%, preferably more than 85%, to light with a wavelength between 400 to 800 nm. The transparent electrode 11 can be formed of a conductive transparent metal oxide selected from ITO (indium-tin oxide), tin oxide, indium oxide, IZO (indium-zinc oxide), zinc oxide, zinc-aluminum oxide, zinc-gallium oxide, and these oxides that are doped with a dopant of fluorine, antimony, or the like. A method for forming the transparent electrode 11 can be selected from an evaporation method, a sputtering method, and a chemical vapor deposition (CVD) method, preferably a sputtering method. When a plurality of electrode elements are needed for the transparent electrode 11 as described later, a layer of conductive transparent metal oxide is first formed uniformly on the whole surface, and then etched to give a desired pattern, forming a transparent electrode 11 consisting of plural electrode elements. Alternatively, a transparent electrode 11 consisting of plural electrode elements is formed using a mask to give a desired pattern.

A transparent electrode 11 formed of the aforementioned materials is suitably used for an anode. When such an electrode is used for a cathode, provision of a cathode buffer layer is desirable at an interface with the organic EL layer 12 to enhance electron injection efficiency. Material for the cathode buffer layer can be selected from alkali metals such as Li, Na, K, and Cs, alkaline earth metals such as Ba and Sr, alloys containing these metals, rare earth metals, and fluorides of these metals, though not limited to these materials. A thickness of the cathode buffer layer can be adequately selected considering a driving voltage and transparency, and is preferably less than 10 nm in normal cases.

An organic EL layer 12 has a structure including at least an organic light emitting layer and as required, a hole injection layer, a hole transport layer, an electron transport layer and/or an electron injection layer. Also possibly employed are a hole injection-transport layer exhibiting both functions of hole injection and hole transportation, and an electron injection-transport layer exhibiting both functions of electron injection and electron transportation. A specific layer structure of the organic EL device can be selected from the following.

(1) Anode/Organic light emitting layer/Cathode

(2) Anode/Hole injection layer/Organic light emitting layer/Cathode

(3) Anode/Organic light emitting layer/Electron injection layer/Cathode

(4) Anode/Hole injection layer/Organic light emitting layer/Electron injection layer/Cathode

(5) Anode/Hole transport layer/Organic light emitting layer/Electron injection layer/Cathode

(6) Anode/Hole injection layer/Hole transport layer/Organic light emitting layer/Electron injection layer/Cathode

(7) Anode/Hole injection layer/Hole transport layer/Organic light emitting layer/Electron transport layer/Electron injection layer/Cathode

Here, each of the anode and a cathode is a transparent electrode 11 or a reflective electrode 13.

Materials of the layers that the organic EL layer 12 is composed of can be selected from known materials. To obtain light emission in blue to blue green spectra, the organic light emitting layer contains for example, a fluorescent brightening agent such as benzothiazole, benzoimidazole, or benzoxazole, metal chelate oxonium compound, styrylbenzene compound, or aromatic dimethylidine compound.

The electron transport layer can be composed of an oxadiazole derivative such as 2-(4-biphenyl)-5-(p-tert-butylphenyl)-1,3,4-oxadiazole PBD, a triazole derivative, a triazine derivative, phenyl-quinoxaline, or aluminum quinolinol complex (Alq₃, for example). The electron injection layer can be composed of, in addition to the above-mentioned materials for the electron transport layer, an aluminum quinolinol complex doped with an alkali metal or an alkaline earth metal.

Material for the hole transport layer can be selected from known materials including triaryl amine compounds such as 4,4′-bis[N-(3-tolyl)-N-phenylamino]biphenyl (TPD), 4,4′-bis[N-(1-naphtyl)-N-phenylamino]-biphenyl (α-NPD), and 4,4′,4″-tris(N-3-tolyl-N-phenylamino) triphenyl amine (m-MTDATA). Material for the hole injection layer can be selected from phthalocyanine compounds such as copper phthalocyanine, and indanthrene compounds.

A reflective electrode 13 is preferably formed of a high reflectivity metal, amorphous alloy, or microcrystalline alloy. The high reflectivity metals include Al, Ag, Mo, W, Ni, and Cr. The high reflectivity amorphous alloys include NiP, NiB, CrP, and CrB. The high reflectivity microcrystalline alloys include NiAl. The reflective electrode can be used for either a cathode or an anode. When the reflective electrode is used for a cathode, the cathode buffer layer as mentioned above can be provided at an interface between the reflective electrode 13 and the organic EL layer 12 to improve electron injection efficiency into the organic EL layer. Electron injection efficiency can also be enhanced by adding a low work function material to the high reflectivity metal, alloy, or microcrystalline alloy. The low work function material can be selected from alkali metals such as lithium, sodium, and potassium, and alkaline earth metals such as calcium, magnesium, and strontium. When the reflective electrode 13 is used for an anode, a layer of the conductive transparent metal oxide as mentioned previously can be provided at an interface between the reflective electrode 13 and the organic EL layer 12 to improve hole injection efficiency into the organic EL layer.

The reflective electrode 13 can be formed by any means known in the art such as evaporation (resistance heating or electron beam heating), sputtering, ion plating, or laser abrasion, corresponding to the material used. When the reflective electrode 13 needs to be formed of a plurality of electrode elements as described later, a mask for giving a desired configuration can be used for forming a reflective electrode 13 consisting of plural electrode elements.

The following describes in further detail about color conversion layer formation by dye-decomposing light 50 in the case of employing three types of color filter layers 2a, 2b, and 2c, and a dye layer 3 containing two types of color conversion dyes (the case of n=3).

FIG. 1A shows a structure including three types of color filter layers 2a, 2b, and 2c, formed on a transparent substrate 1. The organic EL device has a plurality of independent light emitting elements and includes at least a transparent electrode 11, an organic EL layer 12, and a reflective electrode 13.

Dye-decomposing light 50 is irradiated as shown in FIG. 1B from the side of the transparent substrate 1 to form color conversion layers 4a and 4b from the dye layer 3. Since the dye layers are formed in alignment with the specific types of color filter layers, the dye-decomposing light 50 needs to be irradiated perpendicular to the dye layer 3, consequently perpendicular to the transparent substrate 1, also.

The third color filter 2c transmits light in the shortest wavelength region. The dye-decomposing light 51c transmitted through this layer decomposes both first and second color conversion dyes. As a result, a transparent layer 5 that does not contain color conversion dye is formed on the third color filter layer 2c as shown in FIG. 1C. The second color filter layer 2b transmits light in the intermediate wavelength region. The dye-decomposing light 51b transmitted through this layer decomposes the first color conversion dye, but does not decompose the second color conversion dye. As a result, a second color conversion layer 4b containing the second color conversion dye is formed on the second color filter layer 2b as shown in FIG. 1C. The first color filter layer 2a transmits light in the longest wavelength region. The dye-decomposing light 51a transmitted through this layer decomposes neither the first color conversion dye nor the second color conversion dye. As a result, a first color conversion layer 4a that contains the first color conversion dye (and the second color conversion dye) is formed on the first color filter layer 2a as shown in FIG. 1C.

In the area between the color filter layers, the dye-decomposing light 50 transmits right through the area. As a result, the dye layer 3 is decomposed to form a transparent layer 5 similarly to the area on the color filter layer 2c.

When the color filter layers 2a, 2b, and 2c are red (2a), green (2b), and blue (2c) color filter layers, and the first and the second color conversion dyes are red and green color conversion dyes, respectively, the dye-decomposing light 50 preferably includes wavelength component in the range of 500 to 600 nm and wavelength component in the range of shorter than 500 nm, more preferably, the light includes wavelength component in the range of 500 to 600 nm and wavelength component in the range of 450 to 500 nm. The dye-decomposing light 50 in this case can be light including the wavelength component in the range of 450 to 650 nm (that is, white light, for example). The light selected in this wavelength range can effectively transform the dye layer into the color conversion layers without adverse effect on the organic EL layer formed on the dye layer 3. A red color conversion layer 4a containing red and green color conversion dyes is formed on the red color filter layer 2a and a green color conversion layer 4b containing a green color conversion dye is formed on the green color filter layer 2b. On the blue color filter layer 2c and the area between the color filter layers, a transparent layer 5 is formed. Using the thus formed color filter layers 2a, 2b, and 2c, and the color conversion layers 4a and 4a, the wavelength distribution conversion is performed on the light of blue to blue-green color emitted by the organic EL layer to provide an organic EL display capable of full color display.

The dye-decomposing light 50 for use in the exposure includes at least the components that decompose the first color conversion dye and the second color conversion dye. Further, the dye-decomposing light 50 preferably does not include wavelength component that acts on the materials composing the organic EL layer 12. For example, the dye-decomposing light is desired not to include ultraviolet light component. The dye-decomposing light 50 used for the exposure needs to have a much higher intensity than the light that is used for wavelength distribution conversion by the color conversion filter formed by the dye-decomposing light. The desirable intensity is at least 0.05 W/cm², more preferably 1 W/cm² or more on the surface of the transparent substrate receiving the incident light, though depending on the color conversion dye used. The exposure time depends on the degree of decomposition desired for the color conversion dye and can be appropriately determined by those skilled in the art. By using such intense light, the color conversion dye in the desired region can be decomposed.

An alternative method uses plural types of dye-decomposing light each having a different wavelength distribution and conducts a plurality of steps for irradiating the plural types of dye-decomposing light. Each of the plural types of dye-decomposing light includes a wavelength component that decomposes at least one of the color conversion dyes contained in the dye layer 3. Further, every color conversion dye is decomposed by a wavelength component contained in at least one of the plural types of dye-decomposing light. The plurality of steps for irradiating the plural types of dye-decomposing light, though number of steps increases, allows each step to use a light source of narrower wavelength region and higher intensity. It is therefore possible to shorten the time for the irradiation process, or to select the quantity and duration of irradiating light that are optimum for decomposition of each color conversion dye.

A light source of the dye-decomposing light used in the invention can be selected, under the condition of the wavelength described above (for a single irradiation time and for each irradiation time in the plural irradiation steps), from a halogen lamp, a metal halide lamp, an incandescent lamp, a discharge lamp, a mercury lamp, a laser lamp, and other light sources known in the art. An optical filter in combination with these light sources can be used to give a desired wavelength distribution. These light sources (with an optical filter) can be combined with an optical system (including a lens, reflection mirror, etc.) to obtain parallel rays.

Concurrently with the irradiation of dye-decomposing light 50, a bias voltage in the forward direction (hereinafter referred to as a forward voltage) can be applied to the organic EL device 10 to light it. The combined effect of the light emission from the organic EL device 10 and the dye-decomposing light can promote decomposition of the color conversion dyes in the dye layer 3. This bias voltage in the method of invention is, in normal cases, preferably equivalent to the voltage that is used in the operation of displays, and generally in the range of 2 to 10 V. A bias voltage in this range can promote the decomposition of the color conversion dye in the dye layer 3 by the dye-decomposing light without degradation of the organic EL device 10. Therefore, color conversion layers can be generated effectively in a short time.

When the organic EL device 10 comprises a transparent electrode 11 consisting of plural electrode elements, a reflective electrode 13 consisting of plural electrode elements, and a plurality of independent light emitting elements, the bias voltage can be applied to all of the plurality of independent light emitting elements. Alternatively, only some of the plurality of independent light emitting elements may be subjected to the bias voltage. In the structure of FIG. 1B, for example, decomposition of color conversion dyes is not conducted in the region on the first color filter layer 2a. So, the light emitting element corresponding to the first color filter layer 2a need not be lit, and the forward voltage need not be applied. As for the light emitting elements corresponding to the second and third color filter layers 2b and 2c in which decomposition of the one or more types of color conversion dyes is to be promoted, the forward voltage is preferably applied.

Here, in the case of employing plural types of dye-decomposing light with different wavelength distribution as described previously, the bias voltage can be applied, in the process of irradiating dye-decomposing light, only to the light emitting elements corresponding to the position of the color conversion dye that is decomposed by the dye-decomposing light among the plural types of dye-decomposing light. The forward voltage lighting such light emitting elements also promotes decomposition of the color conversion dyes (that is, formation of color conversion layers). In this case, also, the bias voltage can be applied to all of the plurality of independent light emitting elements to light them in the process of irradiating each of the dye-decomposing light.

Further, monitoring can be conducted on the light that is emitted by the bias voltage-applied organic EL device 10 and received through the dye layer 3 (or color conversion layers 4a and 4b), the color filter layers 2a, 2b and 2c, and the transparent substrate 1. With the aid of such monitoring, the quantity of the dye-decomposing light can be adjusted and the termination of the irradiation step can be decided. Specifically, the spectrum or hue is measured on the light through the transparent substrate on application of the forward bias voltage, thereby judging whether desired color conversion layers 4a and 4b have been formed or not. The measurement of the spectrum or hue of the emitted light can be done interrupting the irradiation of the dye-decomposing light or simultaneously with it.

It is possible to apply a bias voltage in the reverse direction (hereinafter referred to as a reverse voltage) on the organic EL device 10 to eliminate microscopic defects in the organic EL layer 12 together with the decomposition of the color conversion dyes in the dye layer 3. The reverse bias voltage in the invented method is normally in the range of 5 to 30 V, preferably in the range of 10 to 20 V. A reverse bias voltage in this range can eliminate microscopic defects in the organic EL layer while transforming the dye layer 3 into color conversion layers 4a and 4b. Consequently, organic EL displays can be manufactured with a higher throughput.

In the step of irradiating dye-decomposing light in the invention, it is further possible to apply forward voltage and reverse voltage alternately on the organic EL device 10 to achieve both the promotion of decomposition of the color conversion dyes and the elimination of microscopic defects in the organic EL layer 12. The values of the forward bias voltage and reverse bias voltage are preferably in the range as described above.

In addition, a series of processes can be performed combining the process of applying a forward voltage, the process of monitoring the light emission during the application of forward bias voltage, and the process of applying a reverse voltage. For example, a cycle constituting the following three steps can be carried out: (1) irradiation of dye-decomposing light and application of a formed bias voltage; (2) irradiation of dye-decomposing light and application of a reverse bias voltage; and (3) interruption of the irradiation of dye-decomposing light, application of a forward voltage, and measurement of spectrum (or hue) of the emitted light. The cycle performs, in combination, transformation of a dye layer to color conversion layers, elimination of microscopic defects in the organic EL layer, and measurement of degree of transformation into the color conversion layers.

For promoting decomposition reaction of the color conversion dyes, a lamination including the dye layer can be heated up. If the heated temperature is also high, thermal decomposition of the color conversion dyes may occur in the whole dye layer, and a color conversion layer may not be formed. The adequate heating temperature differs depending on the type of color conversion dye used. When a rhodamine dye or a coumarin dye is used, change in decomposition speed has been observed at temperatures higher than 60° C., and thermal decomposition has been confirmed to begin at 160° C. The step of irradiation of the dye-decomposing light in the invention can be generally carried out at room temperature. However, the step is preferably conducted at a temperature in the range of 60° C. to 100° C., more preferably in the range of 70° C. to 90° C. The step of heating the dye layer can be carried out by heating the transparent substrate employing the method of convecting or forcedly circulating a heated atmosphere, or by the method of using a radiation source such as an infrared lamp.

A method of manufacturing an organic EL display of a second aspect of the invention comprises steps of: forming n types of color filter layers on a transparent substrate; forming an organic EL device having a plurality of independent light emitting elements on the n types of color filter layers, the organic EL device including at least a first electrode, a second electrode, and an organic EL layer disposed between the first and second electrodes; forming a dye layer containing (n−1) types of color conversion dyes on the organic EL device by means of a dry process; forming a reflective layer on the dye layer; and exposing the dye layer to dye-decomposing light through the transparent substrate and the color filter layers to form an m-th type color conversion layer at a position corresponding to an m-th type color filter layer; wherein n represents an integer from 2 to 6; m represents an integer from 1 to (n−1); each of the n types of color filter layers transmits light in a distinct wavelength region different from each other; the m-th type color conversion dye is decomposed by light that is cut by the m-th type color filter layer; and the m-th type color conversion layer emits light that is transmitted by the m-th type color filter layer, after wavelength distribution conversion.

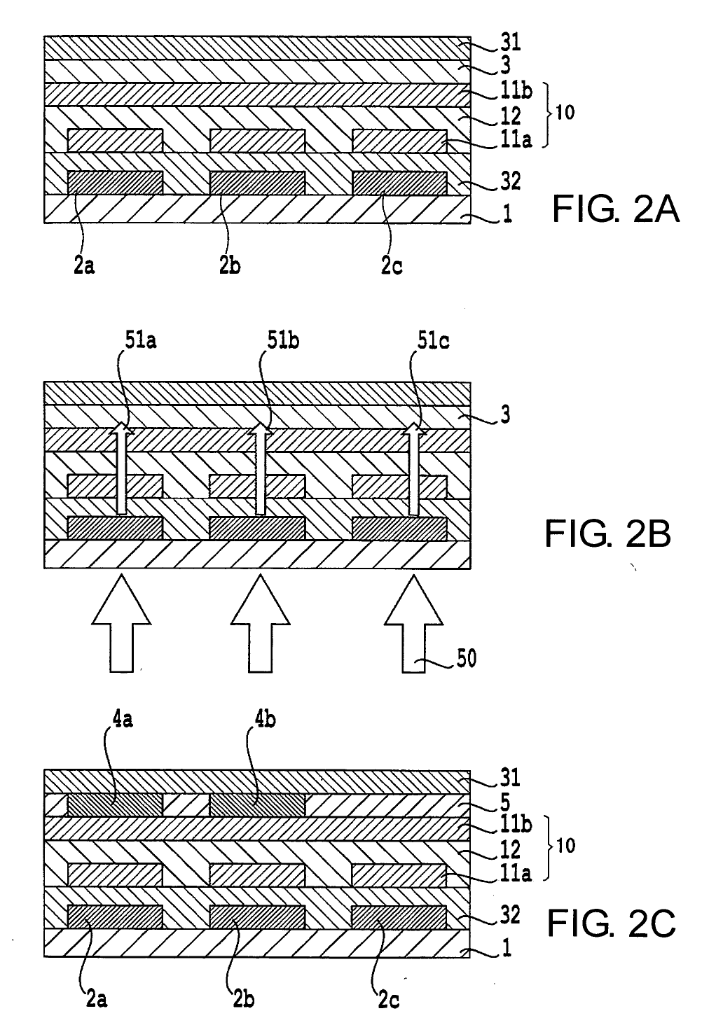

FIG. 2A through 2C schematically show a method of manufacturing an organic EL display according to a second aspect of the invention of the invention, showing an example in the case (of n=3) including three types of color filter layers and two types of color conversion dyes. An organic EL display manufactured by the second aspect of the invention differs from an display obtained by a manufacturing method of the first aspect of the invention in the points of: a second electrode being a transparent electrode as well as a first electrode, a position of forming a dye layer 3 (that becomes color conversion layers 4a and 4b), and existence of a reflective layer 31.

The first electrode is a transparent electrode (a first transparent electrode 11a) same as in the first aspect of the invention, and can be formed using the same material and method for the transparent electrode of the first aspect of the invention. The second electrode is also a transparent electrode (a second transparent electrode 11b) in this aspect of the invention. The second electrode 11b can be formed of the same material as for the first transparent electrode 11a. Though the second transparent electrode 11b can be formed by the same method for the first transparent electrode 11a, when the second transparent electrode is desired to be formed of a plurality of electrode elements, the second electrode 11b is preferably formed using a mask that gives a desired configuration.

A dye layer 3 is formed on the organic EL device 10, specifically, on the second transparent electrode 11b. The dye layer 3 in this aspect of the invention can be formed using the material and method in the first aspect of the invention. In an organic EL display manufactured by this aspect of the invention, a part of the light emitted from the organic EL layer 12 transmits through the color filter layers 2a, 2b and 2c and radiates outwardly, and the other light transmitting through the second electrode (the second transparent electrode 11b) is subjected to wavelength distribution conversion in the color conversion layers 4a and 4b and reflected at the reflective layer 31. Thereafter the light transmits through the color conversion layers 4a and 4b and the color filter layer 2a, 2b and 2c, to radiate outwardly.

The reflective layer 31 reflects a part of the light from the organic EL layer 12 and the light converted in wavelength distribution in the finally obtained color conversion layers 4a and 4b, towards the side of the transparent substrate 1, to radiate towards outside the display. The reflective layer 31 is preferably formed of a high reflectivity metal, amorphous alloy, or microcrystalline alloy, by a dry process including an evaporation method and a sputtering method. The high reflectivity metals include Al, Ag, Mo, W, Ni, and Cr. The high reflectivity amorphous alloys include NiP, NiB, CrP, and CrB. The high reflectivity microcrystalline alloys include NiAl. Since the dye layer 3, the color conversion layers 4a and 4b formed from the dye layer, and the transparent layer 5 are all thin films, the short circuit may occur between the electrode elements of the second transparent electrode 11b through the reflective layer 31. To avoid the short circuit, an insulator layer (not shown in the figure) can be provided between the reflective layer 31 and the dye layer 3, or between the second transparent electrode 11b and the dye layer 3. The insulator layer can be formed of a transparent insulative inorganic material such as TiO₂, ZrO₂, AlOₓ, AlN, or SiNₓ.

In the structure of FIG. 2A through FIG. 2C, a planarizing layer 32 is formed to compensate for the steps due to the color filter layers 2a, 2b and 2c. A material for forming the planarizing layer 32 is desired to exhibit good light transmissivity, to the light having a wavelength in the range of 400 to 800 nm, preferably at least 50%, more preferably more than 85%. The planarizing layer 32 is generally formed by a coating method including spin coating, roll coating, and knife coating. A material for the planarizing layer can be selected from thermoplastic resins including acrylic resins, methacrylic resins, polyester resins such as poly(ethylene terephthalate), polyamide resins, polyimide resins, polyether imide resins, polyacetal resins, polyether sulfone, poly(vinyl alcohol) and its derivatives (such as poly(vinyl butyral), polyphenylene ether, norbornene resins, copolymer resin of isobutylene and maleic anhydride, and cyclic olefin resins; non-photosensitive thermosetting resins including alkyd resins, aromatic sulfone amide resins, urea resins, melamine resins, and benzoguanamine resins; and photochemically-setting resins.

FIG. 2A shows a structure having three types of color filter layers 2a, 2b and 2c, a planarizing layer 32, an organic EL device 10 including at least a first transparent electrode 11a, an organic EL layer 12, and a second transparent electrode 11b and having a plurality of independent light emitting elements, a dye layer 3 containing two types of color conversion dyes, and a reflective layer 31 that are formed on a transparent substrate 1.

Dye-decomposing light 50 is irradiated from the side of the transparent substrate 1 as shown in FIG. 2B to form color conversion layers 4a and 4b from the dye layer 3. Since the color conversion layers in the invented method are formed aligning to the color filter layers, the dye-decomposing light 50 needs to enter the dye layer 3 perpendicularly, and so, perpendicularly to the transparent substrate 1.

In this aspect of the invention, also, the third color filter layer 2c transmits the light in the shortest wavelength region. The dye-decomposing light 51c transmitted through this layer decomposes both the first and the second color conversion dyes. Consequently, in the region corresponding to the third color filter layer 2c, a transparent layer 5 that does not contain color conversion dye is formed as shown in FIG. 2C. The second color filter layer 2b transmits light in the intermediate wavelength region. The dye-decomposing light 51b transmitted through this layer decomposes the first color conversion dye, but does not decompose the second color conversion dye. Consequently, in the region corresponding to the second color filter layer 2b, a second color conversion layer 4b containing the second color conversion dye is formed as shown in FIG. 2C. The first color filter layer 2a transmits the light in the longest wavelength region. The dye-decomposing light 51a transmitted through this layer decomposes neither the first color conversion dye nor second color conversion dye. Consequently, in the region corresponding to the first color filter layer 2a, a first color conversion layer 4a containing the first color conversion dye (as well as the second color conversion dye) is formed as shown in FIG. 2C.

The wavelength distribution, intensity, and irradiation time of the dye-decomposing light can be the same as those in the method of the first aspect of the invention. As in the first aspect of the invention, decomposition of the color conversion dyes can be carried out using plural types of dye decomposing light having different wavelength distribution in this aspect of the invention, also. Further, the bias voltage application in the process of irradiating dye-decomposing light can be conducted as in the first aspect of the invention, the bias voltage including a forward voltage, a reverse voltage, and alternating application of forward and reverse voltages. The radiated light can be monitored in the process of forward voltage application in this aspect of the invention, also, thereby adjusting the quantity of the dye-decomposing light and judging completion of the irradiation step of dye-decomposing light. Moreover in this aspect of the invention, also, the laminate containing the dye layer 3 can be heated in the step of irradiating dye-decomposing light to promote decomposition of the color conversion dyes.

A method of manufacturing an organic EL display according to the third aspect of the invention according to the present invention comprises steps of: forming n types of color filter layers on a transparent substrate; forming an organic EL device having a plurality of independent light emitting elements on the n types of color filter layers by means of a dry process, the organic EL device including at least a first electrode, a second electrode, and an organic EL layer including at least an organic light emitting layer and a carrier-transporting dye layer disposed between the first and second electrodes, the carrier-transporting dye layer including at least (n−1) types of color conversion dyes; and exposing the carrier-transporting dye layer to dye-decomposing light through the transparent substrate and the color filter layers to form an m-th type carrier-transporting color conversion layer at a position corresponding to an m-th type color filter layer; wherein n represents an integer from 2 to 6; m represents an integer from 1 to (n−1); each of the n types of color filter layers transmits light in a distinct wavelength region different from each other; the m-th type color conversion dye is decomposed by light that is cut by the m-th type color filter layer; and the m-th type carrier-transporting color conversion layer emits light that is transmitted by the m-th type color filter layer, after wavelength distribution conversion.

A manufacturing method according to the third aspect of the invention differs from the first aspect of the invention in that the dye layer that is to be transformed into color conversion layers is not separately formed from the organic EL device, but “a carrier-transporting color conversion layer” is introduced in an organic EL layer. The carrier-transporting color conversion layer performs a function of a dye layer as well as the function of injection and transportation of carriers. In this aspect of the invention, (n−1) types of color conversion dyes are introduced in either layer (except for the organic light emitting layer) composing the organic EL layer.

A layer in which color conversion dyes are introduced in this aspect of the invention can be any one of a hole injection layer, a hole transport layer, an electron transport layer, and an electron injection layer; among them, a hole injection layer or an electron injection layer is preferable. In this aspect of the invention, a carrier-transporting color conversion layer is first formed containing a host material and color conversion dyes. This layer is exposed to dye-decomposing light to decompose the color conversion dyes. As a result, a carrier transport layer and a carrier-transporting color conversion layer are formed.

A host material in a carrier-transporting color conversion layer in this aspect of the invention performs functions of carrier injection and/or transportation in the carrier transport layer and the carrier-transporting color conversion layer that are formed after exposure to the dye-decomposing light. When the carrier-transporting color conversion layer is used as a hole injection layer or a hole transport layer, the host material can be selected from hole transport materials of high molecular weight perylene such as BAPP, BABP, CzPP, and CzBP (JP 2004-115441 A). The host material can also be selected from aza-aromatic compounds having an aza-fluoranthene skeleton combined with an aryl amino group(s) (JP 2003-212875 A), condensed aromatic compounds having a fluoranthene skeleton combined with an amino group(s) (see JP 2003-238516 A), triphenylene aromatic compounds having an amino group(s) (see JP 2003-081924 A), and perylene aromatic compounds having an amino group(s) (see WO 2003/048268 A1, equivalent to US 2004/0151944 A1), which all are fluorescent materials exhibiting hole transport property. When the carrier-transporting color conversion layer is used as an electron injection layer or an electron transport layer, Znsq₂ or the like can be used for the host material.

Color conversion dyes that can be used in this aspect of the invention can be selected from dicyanine dyes such as DCM-1, DCM-2, and DCJTB; pyridine materials such as 1-ethyl-2-(4-(p-dimethylamino-phenyl)-1,3-butadienyl)-pyridium-perchlorate (pyridine 1); xanthene derivatives; oxazine materials; coumarin materials; acridine dyes; and condensed aromatic ring materials including diketopyrrolo[3,4-c]pyrrole derivatives, benzoimidazole compounds with a condensed thiazole derivatives, porphyrin derivatives; quinacridone compounds, and bis(aminostyryl)naphthalene compounds.

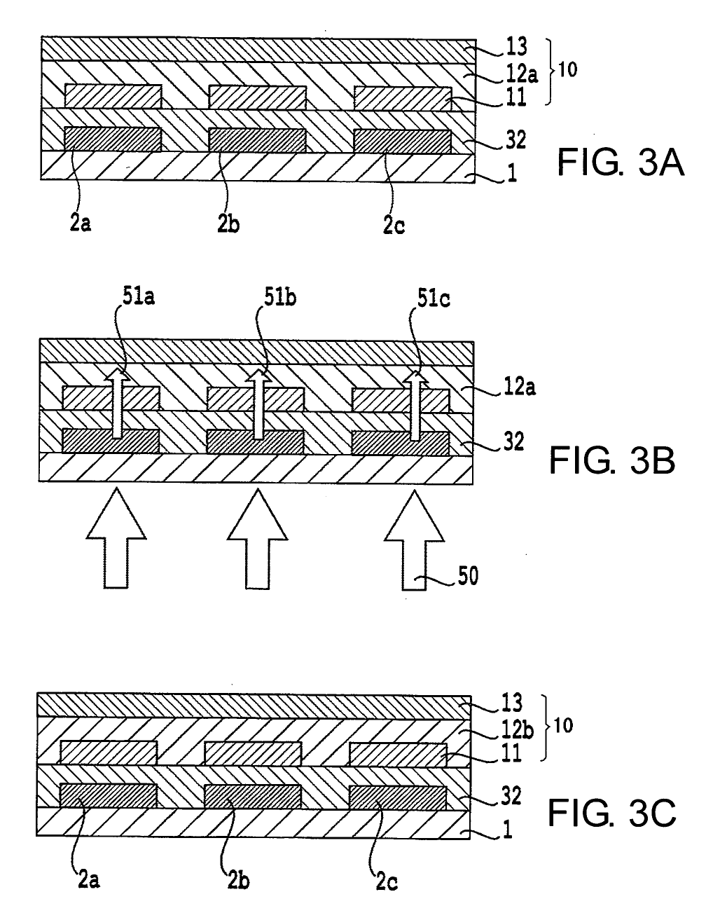

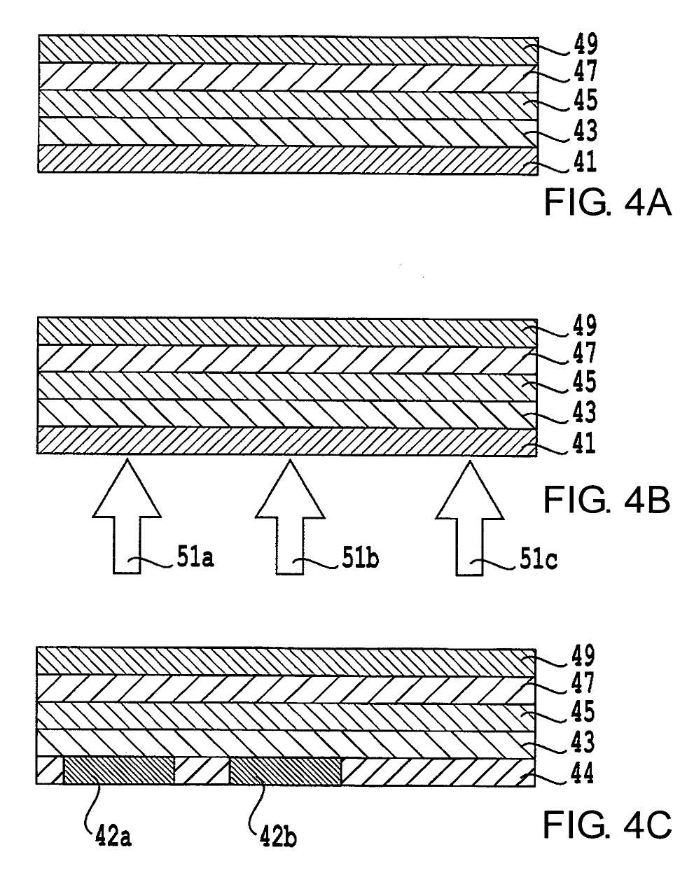

FIG. 3A through 3C and FIG. 4A through 4C show an example of this aspect of the invention using three types of color filter layers 2a, 2b and 2c and a carrier-transporting dye layer 41 containing two types of color conversion dyes (first and second color conversion dyes). FIG. 3A shows a structure comprising three color filter layers 2a, 2b and 2c, a planarizing layer 32, and an organic EL device 10 formed on a transparent substrate 1, the organic EL device 10 comprising a plurality of independent light emitting elements and including at least a transparent electrode 11, an organic EL layer 12a, and a reflective electrode 13. Here, the organic EL layer 12a includes a carrier-transporting dye layer. FIG. 4A shows an example of an organic EL layer 12a consisting of five layers: a hole-injective dye layer 41, a hole transport layer 43, an organic light emitting layer 45, an electron transport layer 47, and an electron injection layer 49. The hole-injective dye layer 41 contains two types of color conversion dyes (first and second color conversion dyes).

Dye-decomposing light 50 is irradiated from the side of transparent substrate 1, as shown in FIG. 3B, to form carrier-transporting color conversion layers from the carrier-transporting dye layer. Since each of the carrier-transporting color conversion layers is formed aligning to the position of a specific type of color filter layer in the invention, the dye-decomposing light 50 needs to enter the transparent substrate 1 perpendicularly to it. The dye-decomposing light 51a, 51b, and 51c transmitted through three types of color filter layers 2a, 2b, and 2c reach the organic EL layer 12a including the carrier-transporting dye layer and decomposes the color conversion dyes, forming an organic EL layer 12b including a carrier transport layer and two types of carrier-transporting color conversion layers, as shown in FIG. 3C.

In more detail, as shown in FIG. 4B, the organic EL layer 12a receives the light 51a, 51b, and 51c transmitted through the first to third color filter layers 2a, 2b, and 2c. The third color filter layer 2c transmits the light in the shortest wavelength region. The dye-decomposing light 51c transmitted through this layer decomposes both the first and the second color conversion dyes. Consequently, in the region corresponding to the third color filter layer 2c, a hole injection layer 44 that does not contain color conversion dye is formed as shown in FIG. 4C. The second color filter layer 2b transmits light in the intermediate wavelength region. The dye-decomposing light 51b transmitted through this layer decomposes the first color conversion dye, but does not decompose the second color conversion dye. Consequently, in the region corresponding to the second color filter layer 2b, a second hole-transporting color conversion layer 42b containing the second color conversion dye is formed as shown in FIG. 4C. The first color filter layer 2a transmits the light in the longest wavelength region. The dye-decomposing light 51a transmitted through this layer decomposes neither the first color conversion dye nor second color conversion dye. Consequently, in the region corresponding to the first color filter layer 2a, a first hole-injective color conversion layer 42a containing the first color conversion dye (as well as the second color conversion dye) is formed as shown in FIG. 4C. Thus, an organic EL layer 12b is formed including two types of hole-injective color conversion layers 42a and 42b, and a hole injection layer 44.

The wavelength distribution, intensity, and irradiation time of the dye-decomposing light can be the same as those in the method of the first aspect of the invention. As in the first aspect of the invention, decomposition of the color conversion dyes can be carried out using plural types of dye decomposing light having different wavelength distribution. Further, the bias voltage application in the process of irradiating dye-decomposing light can be conducted as in the first aspect of the invention, the bias voltage including a forward voltage, a reverse voltage, and alternating application of forward and reverse voltages. The radiated light can be monitored in the process of forward voltage application in this aspect of the invention, also, thereby adjusting the quantity of the dye-decomposing light and judging completion of the irradiation step of dye-decomposing light. Moreover in this aspect of the invention, also, the laminate including the carrier-transporting dye layer 3 can be heated in the step of irradiating dye-decomposing light to promote decomposition of the color conversion dyes.

A method of manufacturing an organic EL display according to the fourth aspect of the invention comprises steps of: forming n types of color filter layers on a transparent substrate; forming a dye layer containing (n−1) types of color conversion dyes dispersed in a resin on the n types of color filter layers; forming an organic EL device having a plurality of independent light emitting elements on the dye layer, the organic EL device including at least a first electrode, a second electrode, and an organic EL layer disposed between the first and second electrodes; and exposing the dye layer to dye-decomposing light through the transparent substrate and the color filter layers to form an m-th type color conversion layer at a position corresponding to an m-th type color filter layer; wherein n represents an integer from 2 to 6; m represents an integer from 1 to (n−1); each of the n types of color filter layers transmits light in a distinct wavelength region different from each other; the m-th type color conversion dye is decomposed by light that is cut by the m-th type color filter layer; and the m-th type color conversion layer emits light that is transmitted by the m-th type color filter layer, after wavelength distribution conversion.

The manufacturing method according to this aspect of the invention differs from the manufacturing method of the first aspect of the invention in that a dye layer is not formed from evaporated color conversion dyes but from color conversion dyes dispersed in a resin.

The resin dispersing the color conversion dyes, a so-called matrix resin, can be selected from various thermoplastic resins. The matrix resin is desired not to decompose or distort in heating process at a temperature of normally about 100° C., preferably 150° C. Useful matrix resins include, for example, acrylic resin such as polymethacrylate, alkyd resin, aromatic hydrocarbon resin (such as polystyrene), cellulose resin, and polyester resin (such as poly(ethylene terephthalate)), polyamide resin (such as nylon), polyurethane resin, poly(vinyl acetate) resin, poly (vinyl alcohol) resin, and mixtures of these resins. The color conversion dyes described in the first aspect of the invention can be used for the color conversion dyes in this aspect of the invention, also.

A dye layer 63 in this aspect of the invention (that is a resin layer dispersing color conversion dyes) can be formed by applying a coating liquid that is prepared by dispersing or dissolving (n−1) types of color conversion dyes and a matrix resin in an appropriate solvent by means of a method known in the art (selected from spin coating, roll coating, knife coating, casting, screen printing, and the like). The color conversion dye in this aspect of the invention is used in an amount of at least 0.2 micro mol per 1 g of matrix resin, preferably in the range of 1 to 20 micro mol, more preferably in the range of 3 to 15 micro mol. A dye layer 63 in this aspect of the invention has a thickness of at least 5 μm, preferably in the range of 7 to 15 μm. Consequently, color conversion layers transformed from the dye layer have also a thickness in this range and can emit color-converted output light with a desirable intensity.

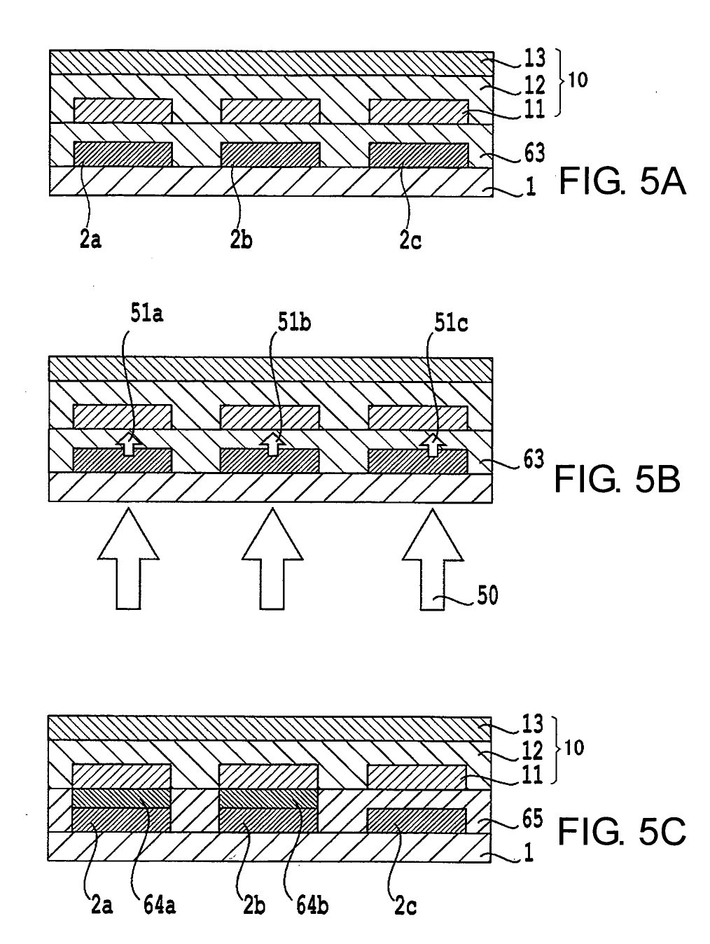

FIG. 5A through 5C show an example (in the case of n=3) of this aspect of the invention using three types of color filter layers and two types of color conversion dyes. FIG. 5A shows a structure comprising three types of color filter layers 2a, 2b, and 2c, a dye layer 63 containing two types of color conversion dyes (first and second color conversion dyes) and an organic EL device 10 formed on a transparent substrate 1, the organic EL device 10 having a plurality of independent light emitting elements and including at least a transparent electrode 11, an organic EL layer 12, and a reflective electrode 13.

Dye-decomposing light 50 is irradiated from the side of the transparent substrate 1 as shown in FIG. 5B to form color conversion layers 64a and 64b from the dye layer 63. Since the color conversion layers in the invented method are formed aligning to the color filter layers, the dye-decomposing light 50 needs to enter the dye layer 63 perpendicularly, and so, perpendicularly to the transparent substrate 1, also. The third color filter layer 2c transmits the light in the shortest wavelength region. The dye-decomposing light 51c transmitted through this layer decomposes both the first and the second color conversion dyes. Consequently, in the region corresponding to the third color filter layer 2c, a transparent layer 65 that does not contain color conversion dye is formed as shown in FIG. 5C. The second color filter layer 2b transmits light in the intermediate wavelength region. The dye-decomposing light 51b transmitted through this layer decomposes the first color conversion dye, but does not decompose the second color conversion dye. Consequently, in the region corresponding to the second color filter layer 2b, a second color conversion layer 64b containing the second color conversion dye is formed as shown in FIG. 5C. The first color filter layer 2a transmits the light in the longest wavelength region. The dye-decomposing light 51a transmitted through this layer decomposes neither the first color conversion dye nor second color conversion dye. Consequently, in the region corresponding to the first color filter layer 2a, a first color conversion layer 64a containing the first color conversion dye (as well as the second color conversion dye) is formed as shown in FIG. 5C.

The wavelength distribution, intensity, and irradiation time of the dye-decomposing light can be the same as those in the method of the first aspect of the invention. As in the first aspect of the invention, decomposition of the color conversion dyes can be carried out using plural types of dye decomposing light having different wavelength distribution in this aspect of the invention, also. Further, the bias voltage application in the process of irradiating dye-decomposing light can be conducted as in the first aspect of the invention, the bias voltage including a forward voltage, a reverse voltage, and alternating application of forward and reverse voltages. The radiated light can be monitored in the process of forward voltage application in this aspect of the invention, also, thereby adjusting the quantity of the dye-decomposing light and judging completion of the irradiation step of dye-decomposing light. Moreover in this aspect of the invention, also, the laminate including the dye layer 63 containing a resin can be heated in the step of irradiating dye-decomposing light to promote decomposition of the color conversion dyes.

A method of manufacturing an organic EL display according to the fifth aspect of the invention comprises steps of: forming n types of color filter layers on a transparent substrate; forming an organic EL device having a plurality of independent light emitting elements on a second substrate, the organic EL device including at least a first electrode, a second electrode, and an organic EL layer disposed between the first and second electrodes; forming a dye layer containing (n−1) types of color conversion dyes on the organic EL device; combining the transparent substrate and the second substrate together such that the color filter layers are opposing the dye layer; and exposing the dye layer to dye-decomposing light through the transparent substrate and the color filter layers to form an m-th type color conversion layer at a position corresponding to an m-th type color filter layer; wherein n represents an integer from 2 to 6; m represents an integer from 1 to (n−1); each of the n types of color filter layers transmits light in a distinct wavelength region different from each other; the m-th type color conversion dye is decomposed by light that is cut by the m-th type color filter layer; and the m-th type color conversion layer emits light that is transmitted by the m-th type color filter layer, after wavelength distribution conversion.

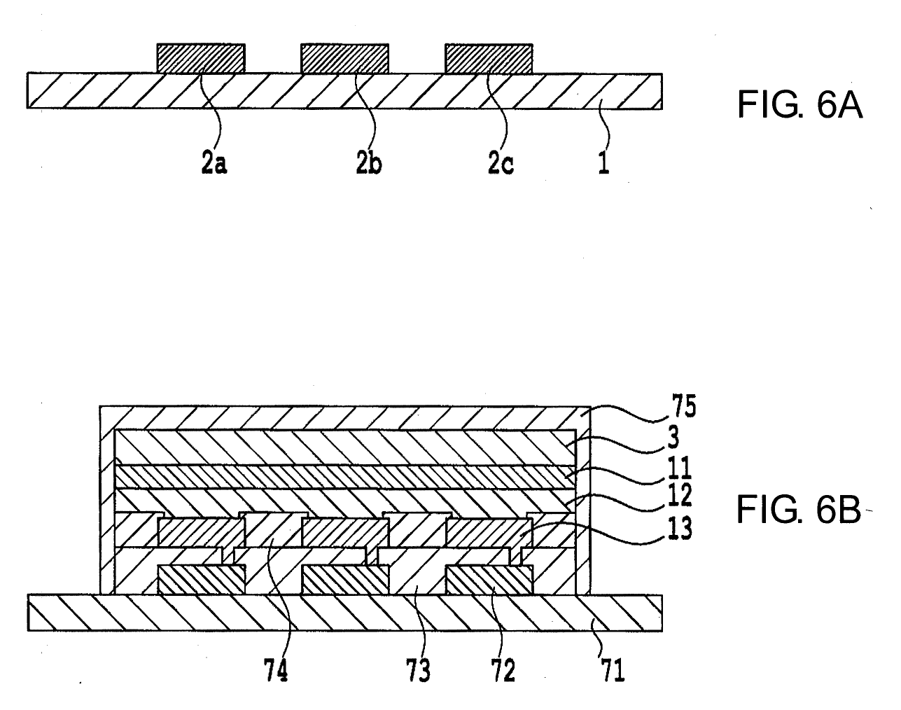

A method according to this aspect of the invention differs from the method of the first aspect of the invention in that color filter layers are formed on a transparent substrate and an organic EL device and a dye layer are formed on another substrate, a second substrate, separated from the transparent substrate, and then, the two substrates are combined together to obtain a laminate ready for forming color conversion layers in a self alignment manner. FIGS. 6A and 6B show the laminates before combination for the case (n=3) using three types of color filter layers and two types of color conversion dyes. FIG. 6A shows a laminate of a transparent substrate and a color filter layers. FIG. 6B shows a laminate of second substrate, an organic EL device, and a dye layer. A material of the color filter layer can be selected from the materials shown in the description of the first aspect of the invention. The laminate of a transparent substrate and a color filter layers shown in FIG. 6A can be manufactured by the method as in the first aspect of the invention.

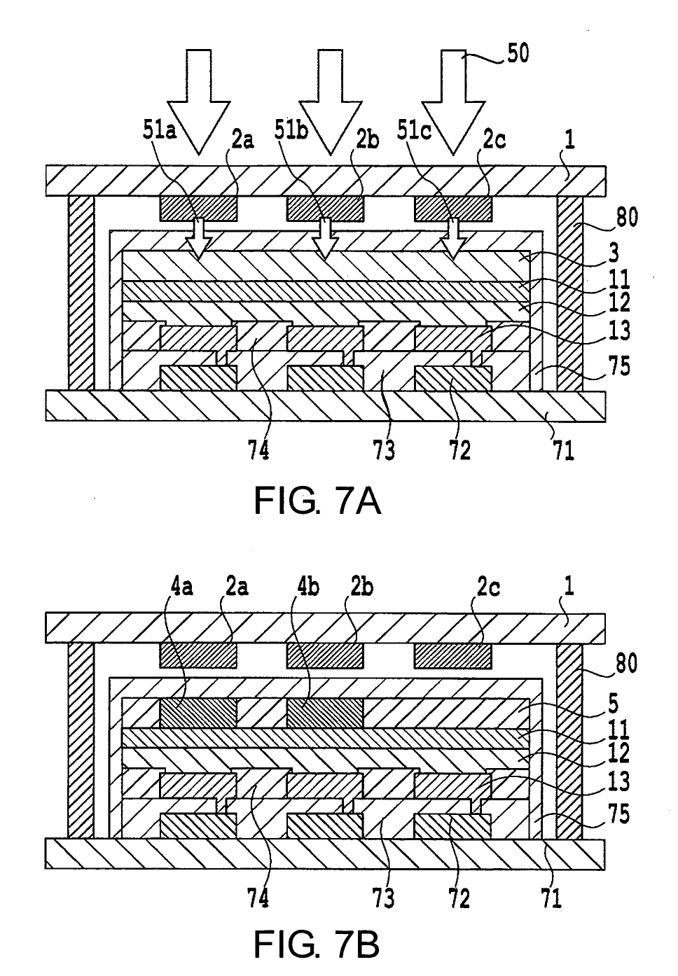

FIGS. 7A and 7B show an example of the laminate after combination. FIG. 7A illustrates exposure of the laminate to the dye-decomposing light, and FIG. 7B illustrates a structure of the obtained organic EL display. In the structure shown in FIGS. 6A and 6B, and FIGS. 7A and 7B, a first electrode is the reflective electrode 13 and a second electrode is the transparent electrode 11.

A second substrate 71 used in this aspect of the invention can be transparent or opaque. A transparent material for forming the second substrate 71 can be the same material as the transparent substrate of the first aspect of the invention. An opaque material for forming the second substrate 71 can be a semiconductor substrate such as a silicon wafer. This aspect of the invention can readily provide a plurality of switching elements 72 on the second substrate 71 to form an organic EL device of an active matrix driving mode. The plurality of switching elements 72 can be TFTs, MIMs, or the like. The switching elements 72 can be covered with a planarizing insulator film 73 to planarize the surface, except for the openings for electrical connection to the first electrode. The switching elements 72 and the planarizing insulator film 73 can be formed by any method known in the art.

Then, an organic EL device is formed by laminating a reflective electrode 13 (a first electrode), an organic EL layer 12, and a transparent electrode 11 (a second electrode). The layers of the organic EL device can be fabricated by the same materials and methods as in the first aspect of the invention.

When a plurality of switching elements 72 are provided on the second substrate 71 as shown in FIG. 6B, the reflective electrode 13 consists of plural electrode elements each defining an independent light emitting element, and each electrode element electrically connects to a switching element 72 in one-to-one correspondence. Optionally, an insulation film 74 can be provided between the electrode elements of the reflective electrode 13 to prevent short circuit between the electrode elements. The insulation film 74 can be fabricated using any material such as metal oxide or metal nitride and a technique known in the art. In the structure of FIG. 6B, the transparent electrode 11 is a single common electrode formed over the whole surface.

Then, a dye layer 3 is formed on the organic EL device. The dye layer in this aspect of the invention contains (n−1) types of color conversion dyes and formed by a dry process, as in the first aspect of the invention.

As shown in FIG. 6B, a passivation layer 75 can be formed covering the structural elements including the dye layer 3 and the lower parts. The passivation layer 75 is effective for preventing oxygen, low molecular-weight components, and moisture from penetrating from the external environment into the organic EL layer 12 and/or the color conversion layers (transformed from the dye layer 3), thus, avoiding degradation of these layers. The passivation layer 75 is formed of a material that exhibits high transparency in the visible light region (transmissivity at least 50% in the range of 400 to 800 nm), electrical insulation property, barrier performance against moisture, oxygen and low molecular-weight components, and film hardness preferably pencil hardness of 2H or higher. Useful materials include inorganic oxides and nitrides such as SiOₓ, SiNₓ, SiNₓO_{y}, AlOₓ, TiOₓ, TaOₓ, and ZnOₓ. The passivation layer can be formed by a commonly used technique such as a sputtering method, a CVD method, a vacuum evaporation method, a dipping method, or a sol-gel method without any special limitation. Thickness of the passivation layer 75 (total thickness in the case of a laminate of plural layers,) is preferably in the range of 0.1 to 10 μm.

The thus obtained laminate of the transparent substrate and the color filter layer, and the laminate of the second substrate, the organic EL device, and the dye layer are combined together such that the transparent substrate 1 and the second substrate 71 locate outermost, that is, the color filter layers 2a, 2b, and 2c, and the dye layer 3 are opposing each other (FIG. 7A). An adhesive layer 80 can be used for combining the two laminates providing the adhesive layer around the transparent substrate 1 or the second substrate 71. The adhesive layer 80 can be formed of an ultraviolet light-setting adhesive. Spacer particles such as glass beads, silica beads or the like can be contained to define the distance between the transparent substrate and the second substrate 71.

Then, as shown in FIG. 7A, dye-decomposing light 50 is irradiated on the dye layer through the transparent substrate 1 and the color filter layers 2a, 2b, and 2c to form color conversion layers, as in the first aspect of the invention. FIGS. 7A and 7B show an example of structure in the case (n=3) using three color filter layers 2a, 2b, and 2c and a dye layer 3 containing two types of color conversion dyes. In the region corresponding to the third color filter layer 2c that transmits the light in the shortest wavelength region, and the region without color filter layer, both the two color conversion dyes are decomposed to form a transparent layer 5. In the region corresponding to the second color filter layer 2b that transmits the light in the intermediate wavelength region, the first color conversion dye is decomposed to form the second color conversion layer 4b containing the second color conversion dye. In the region corresponding to the first color filter layer 2a that transmits the light in the longest wavelength region, no color conversion dye is decomposed to form the first color conversion layer 4a containing the first and the second color conversion dyes. When the first to third color filter layers are red (2a), green (2b), and blue (2c) color filters, and the first and second color conversion layers are red (4a) and green (4b) color conversion layers, for example, an organic EL display capable of full color display can be obtained as shown in FIG. 7B.

In this aspect of the invention, as in the first aspect of the invention, irradiation can also be performed plural times, each irradiating distinctive dye-decomposing light, application of a forward bias voltage in the process of irradiating the dye-decomposing light, and light quantity control of the dye-decomposing light based on the emission spectrum on application of the forward bias voltage. In this aspect of the invention, also, the temperature of the laminate including the dye layer 3 can be raised in the process of irradiating the dye-decomposing light, as in the first aspect of the invention. Suitable heating temperature is same as in the first aspect of the invention. The temperature of the dye layer 3 in this aspect of the invention can be raised by heating the transparent substrate 1, the second substrate 71, or both of the substrates.

This aspect of the invention, in which n types of color filter layers and a dye layer for obtaining color conversion layers are formed on separate substrates, has been described in relation to an organic EL device of an active matrix driving system. However, this aspect of the invention is also useful in an organic EL device of a passive matrix driving system. In that case, the switching elements 72 and the accompanying parts are omitted, and the reflective electrode 13 is composed of a plurality of electrode elements in a stripe pattern extending in one direction and the transparent electrode 11 is composed of a plurality of electrode elements in a stripe pattern extending in another direction crossing the former direction. Thus, an organic EL display of a passive matrix driving system can be constructed.

### EXAMPLES

### Example 1

Blue color filter material (Color Mosaic CB-7001, a product of FUJIFILM Electronic Materials Co., Ltd.) was applied on a transparent glass substrate (Corning 1737 glass) by a spin coating method, and patterned by a photolithography method, to form a blue color filter layer of plural strips extending in the longitudinal direction having a line width of 0.1 mm, a pitch of 0.33 mm (distance between two adjacent lines being 0.23 mm), and a film thickness of 2 μm.

On the substrate having the blue color filter layer, a green color filter material (Color Mosaic CG-7001, a product of FUJIFILM Electronic Materials Co., Ltd.) was applied by a spin coating method, and patterned by a photolithography method, to form a green color filter layer of plural stripes extending in the longitudinal direction having a line width of 0.1 mm, a pitch of 0.33 mm, and a film thickness of 2 μm.

Next, a red color filter material (Color Mosaic CR-7001, a product of FUJIFILM Electronic Materials Co., Ltd.) was applied by a spin coating method, and patterned by a photolithography method, to form a red color filter layer of plural stripes extending in the longitudinal direction having a line width of 0.1 mm, a pitch of 0.33 mm, and a film thickness of 2 μm.

The substrate having the three types of color filter layers was set in a vacuum evaporation apparatus, and coumarin 6 and DCM-1 were co-evaporated to form a dye layer with a film thickness of 500 nm. The temperature of each crucible was controlled so as to adjust the evaporation speed for coumarin 6 at 0.3 nm/s and the evaporation speed for DCM-1 at 0.6 nm/s. In the dye layer in this Example, the molar ratio of coumarin 6:DCM-1 was 3:7.

The laminate having the dye layer deposited thereon was transferred into a facing target sputtering apparatus. A mask was positioned that gives a film of plural stripes extending in the longitudinal direction having a line width of 0.1 mm and a pitch of 0.11 mm, and by depositing indium-tin oxide (ITO) through this mask to a thickness of 200 nm, a transparent electrode was obtained.

Then, without breaking the vacuum, the laminate having the transparent electrode formed thereon was transferred into a vacuum evaporation apparatus, and sequentially deposited were four layers of a hole injection layer, a hole transport layer, a light emitting layer, and an electron transport layer, to obtain an organic EL layer. Each layer was deposited at an evaporation speed of 0.1 nm/s. The hole injection layer was a layer of copper phthalocyanine (CuPc) 100 nm thick; the hole transport layer was a layer of α-NPD 10 nm thick; the light emitting layer was a DPVBi 30 nm thick; and the electron transport layer was a layer of Alq₃ with a film thickness of 20 nm. Subsequently, depositing lithium to a thickness of 1.5 nm, a cathode buffer layer was formed.

After that, a mask was positioned that gives a film of plural stripes extending in the transverse direction having a line width of 0.1 mm and a pitch of 0.11 mm. A CrB film was deposited through this mask to a thickness of 200 nm to obtain a reflective electrode.

Finally, the laminate having the reflective electrode formed thereon was taken out to a dry atmosphere (moisture concentration at most 1 ppm and oxygen concentration at most 1 ppm). The laminate was sealed off by bonding a sealing glass substrate with ultraviolet light-setting adhesive applied on the four sides thereof.

The sealed laminate was illuminated by dye-decomposing light with an intensity of 1 W/cm² from a carbon arc lamp (a white light source) located in the side of the transparent glass substrate through an optical system for obtaining parallel rays. In the region of the dye layer corresponding to the red color filter layer, neither coumarin 6 nor DCM-1 decomposed, and a red color conversion layer was formed in this region. In the region of the dye layer corresponding to the green color filter layer, coumarin 6 did not decompose and DCM-1 decomposed, and a green color conversion layer was formed in this region. In the region of the dye layer corresponding to the blue color filter layer and the region without any color filter layer, both coumarin 6 and DCM-1 decomposed, and a transparent layer was formed in this region.

The two types of color conversion layers in the organic EL display obtained by irradiation of dye-decomposing light were disposed corresponding to the color filter layers, and a fault such as distortion was not observed.

### Example 2

An organic EL display was manufactured in the same manner as in Example 1 except that a forward bias voltage of 10 V was applied on the organic EL layer, linearly and sequentially scanning the transparent electrode elements and the reflective electrode elements in the process of dye-decomposing light irradiation. In this example, the irradiation time of the dye-decomposing light was shortened by 30% as compared with in Example 1, demonstrating promotion of decomposition of the color conversion dye in the dye layer by the emission from the organic EL layer.

### Example 3

An organic EL display was manufactured in the same manner as in Example 2 except that the light emitting elements in the area corresponding to the red color filter layer was not lit in the process of the linear and sequential scanning of the transparent electrode elements and the reflective electrode elements. In this Example, also, as in Example 2, the irradiation time of the dye-decomposing light was shortened by 30% as compared with in Example 1, demonstrating promotion of decomposition of the color conversion dye in the dye layer by the emission from the organic EL layer.

### Example 4

An organic EL display was manufactured in the same manner as in Example 1 except that a reverse bias voltage of 20 V was applied on the organic EL layer, linearly and sequentially scanning the transparent electrode elements and the reflective electrode elements in the process of dye-decomposing light irradiation. No microscopic defect has been observed in the light emitting elements of the organic EL display obtained in this Example, demonstrating possibility of elimination of microscopic defects in the light emitting elements simultaneously with the formation of color conversion layers by irradiation of dye-decomposing light.

### Example 5

An organic EL display was manufactured in the same manner as in Example 2 except that each of the light emitting elements was subjected to ten times of application of alternate forward bias voltage (10 V) and reverse bias voltage (20 V) in the process of the linear and sequential scanning of the transparent electrode elements and the reflective electrode elements. In this Example, also, the irradiation time of the dye-decomposing light was shortened by 30% as compared with in Example 1, demonstrating promotion of decomposition of the color conversion dye in the dye layer by the emission from the organic EL layer. It has been further clarified that no microscopic defect has been observed in the light emitting elements of the organic EL display obtained in this Example, demonstrating possibility of elimination of microscopic defects in the light emitting elements simultaneously with the formation of color conversion layers by irradiation of dye-decomposing light.

### Example 6

An organic EL display was manufactured in the same manner as in Example 1 except that the laminate was heated to 65° C. in the process of irradiation of dye-decomposing light. In this Example, the irradiation time of the dye-decomposing light was shortened by 20% as compared with in Example 1, demonstrating promotion of decomposition of the color conversion dye in the dye layer by heating the laminate.

### Example 7

An organic EL display was manufactured in the same manner as in Example 1 except that the process of irradiation of dye-decomposing light was conducted in the two steps as described below.

On the laminate, a type of dye-decomposing light with an intensity of 1 W/cm² was irradiated from a carbon arc lamp (a white light source) located in the side of the transparent glass substrate through a band-pass filter that transmits light with wavelength in the range of 500 to 600 nm and an optical system for obtaining parallel rays. In the region of the dye layer over the green color filter layer and the blue color filter layer, and the region without any color filter layer, DCM-1 decomposed in this irradiation process.

Another type of dye-decomposing light with an intensity of 1 W/cm² was irradiated from a carbon arc lamp (a white light source) located in the side of the transparent glass substrate through a band-pass filter that transmits light with wavelength in the range of 450 to 510 nm and an optical system for obtaining parallel rays. In the region of the dye layer over the blue color filter layer, and the region without any color filter layer, coumarin 6 decomposed in this irradiation process.

By the two steps of irradiation of dye-decomposing light as described above, in the region of the dye layer over the red color filter layer, neither coumarin 6 nor DCM-1 decomposed, forming a red color conversion layer in this region. In the region of the dye layer over the green color filter layer, coumarin 6 did not decompose and DCM-1 decomposed, forming a green color conversion layer in this region. In the region of dye layer over the blue color filter layer and the region without any color filter layer, both coumarin 6 and DCM-1 decomposed, forming a transparent layer in this region.

### Example 8

A laminate having three types of color filter layers formed thereon was fabricated in the same manner as in Example 1. Then, the laminate was transferred into a facing target sputtering apparatus. A mask was positioned that gives a film of plural stripes extending in the longitudinal direction having a line width of 0.1 mm and a pitch of 0.11 mm, and by depositing ITO through this mask to a thickness of 200 nm, a first transparent electrode was obtained.

Then, in the same manner as in Example 1, sequentially deposited on the laminate were four layers of a hole injection layer, a hole transport layer, a light emitting layer, and an electron transport layer, to obtain an organic EL layer. Subsequently, depositing lithium to a thickness of 1.5 nm, a cathode buffer layer was formed.

The laminate having the cathode buffer layer formed thereon was transferred into a facing target sputtering apparatus. A mask was positioned that gives a film of plural stripes extending in the transverse direction having a line width of 0.1 mm and a pitch of 0.11 mm, and by depositing ITO through this mask to a thickness of 200 nm, a second transparent electrode was obtained.

The substrate having the second transparent electrode was set in a vacuum evaporation apparatus, and coumarin 6 and DCM-1 were co-evaporated to form a dye layer with a film thickness of 500 nm. The temperature of each crucible was controlled so as to adjust the evaporation speed for coumarin 6 at 0.3 nm/s and the evaporation speed for DCM-1 at 0.6 nm/s. In the dye layer in this Example, the molar ratio of coumarin 6:DCM-1 was 3:7. Then, a CrB film 200 nm thick was deposited by an evaporation method to obtain a reflective layer.

After that, the laminate having the reflective layer formed thereon was taken out to a dry atmosphere (moisture concentration at most 1 ppm and oxygen concentration at most 1 ppm). The laminate was sealed off by bonding a sealing glass substrate with ultraviolet light-setting adhesive applied on the four sides thereof.

The sealed laminate was illuminated by dye-decomposing light with an intensity of 1 W/cm² from a carbon arc lamp (a white light source) located in the side of the transparent glass substrate through an optical system for obtaining parallel rays. In this process of dye-decomposing light irradiation, in the region of the dye layer corresponding to the red color filter layer, neither coumarin 6 nor DCM-1 decomposed, and a red color conversion layer was formed in this region. In the region of the dye layer corresponding to the green color filter layer, coumarin 6 did not decompose and DCM-1 decomposed, and a green color conversion layer was formed in this region. In the region of the dye layer corresponding to the blue color filter layer and the region without any color filter layer, both coumarin 6 and DCM-1 decomposed, and a transparent layer was formed in this region.

The two types of color conversion layers in the organic EL display obtained by irradiation of dye-decomposing light were disposed corresponding to the color filter layers, and a fault such as distortion was not observed.

### Example 9

An organic EL display was manufactured in the same manner as in Example 8 except that a forward bias voltage of 10 V was applied on the organic EL layer, linearly and sequentially scanning the first and second transparent electrode elements in the process of dye-decomposing light irradiation. In this example, the irradiation time of the dye-decomposing light was shortened by 30% as compared with in Example 8, demonstrating promotion of decomposition of the color conversion dye in the dye layer by the emission from the organic EL layer.

### Example 10

An organic EL display was manufactured in the same manner as in Example 8 except that the light emitting elements in the area corresponding to the red color filter layer was not lit in the process of the linear and sequential scanning of the first and second transparent electrode elements. In this Example, also, as in Example 9, the irradiation time of the dye-decomposing light was shortened by 30% as compared with in Example 8, demonstrating promotion of decomposition of the color conversion dye in the dye layer by the emission from the organic EL layer.

### Example 11

An organic EL display was manufactured in the same manner as in Example 8 except that a reverse bias voltage of 20 V was applied on the organic EL layer, linearly and sequentially scanning the first and second electrode elements in the process of dye-decomposing light irradiation. No microscopic defect has been observed in the light emitting elements of the organic EL display obtained in this Example, demonstrating possibility of elimination of microscopic defects in the light emitting elements simultaneously with the formation of color conversion layers by irradiation of dye-decomposing light.

### Example 12

An organic EL display was manufactured in the same manner as in Example 9 except that each of the light emitting elements was subjected to ten times of application of alternate forward bias voltage (10 V) and reverse bias voltage (20 V) in the process of the linear and sequential scanning of the first and second transparent electrode elements. In this Example, also, the irradiation time of the dye-decomposing light was shortened by 30% as compared with in Example 8, demonstrating promotion of decomposition of the color conversion dye in the dye layer by the emission from the organic EL layer. It has been further clarified that no microscopic defect has been observed in the light emitting elements of the organic EL display obtained in this Example, demonstrating possibility of elimination of microscopic defects in the light emitting elements simultaneously with the formation of color conversion layers by irradiation of dye-decomposing light.

### Example 13

An organic EL display was manufactured in the same manner as in Example 8 except that the laminate was heated to 65° C. in the process of irradiation of dye-decomposing light. In this Example, the irradiation time of the dye-decomposing light was shortened by 20% as compared with in Example 8, demonstrating promotion of decomposition of the color conversion dye in the dye layer by heating the laminate.

### Example 14

An organic EL display was manufactured in the same manner as in Example 8 except that the process of irradiation of dye-decomposing light was conducted in the two steps as described below.

On the laminate, a type of dye-decomposing light with an intensity of 1 W/cm² was irradiated from a carbon arc lamp (a white light source) located in the side of the transparent glass substrate through a band-pass filter that transmits light with wavelength in the range of 500 to 600 nm and an optical system for obtaining parallel rays. In the region of the dye layer over the green color filter layer and the blue color filter, and the region without any color filter layer, DCM-1 decomposed in this irradiation process.

Another type of dye-decomposing light with an intensity of 1 W/cm² was irradiated from a carbon arc lamp (a white light source) located in the side of the transparent glass substrate through a band-pass filter that transmits light with wavelength in the range of 450 to 510 nm and an optical system for obtaining parallel rays. In the region of the dye layer over the blue color filter, and the region without any color filter layer, coumarin 6 decomposed in this irradiation process.

By the two steps of irradiation of dye-decomposing light as described above, in the region of the dye layer over the red color filter layer, neither coumarin 6 nor DCM-1 decomposed, forming a red color conversion layer in this region. In the region of the dye layer over the green color filter layer, coumarin 6 did not decompose and DCM-1 decomposed, forming a green color conversion layer in this region. In the region of dye layer over the blue color filter layer and the region without any color filter layer, both coumarin 6 and DCM-1 decomposed, forming a transparent layer in this region.

### Example 15

A laminate having three types of color filter layers formed thereon was fabricated in the same manner as in Example 1. Then, the laminate was transferred into a facing target sputtering apparatus. A mask was positioned that gives a film of plural stripes extending in the longitudinal direction having a line width of 0.1 mm and a pitch of 0.11 mm, and by depositing ITO through this mask to a thickness of 200 nm, a transparent electrode was obtained.

Then, without breaking the vacuum, the laminate having the transparent electrode formed thereon was transferred into a vacuum evaporation apparatus, and sequentially deposited were four layers of a hole-injective dye layer, a hole transport layer, a light emitting layer, and an electron transport layer, to obtain an organic EL layer. Each layer was deposited at an evaporation speed of 0.1 nm/s. The hole-injective dye layer was a layer 200 nm thick of CzPP: (coumarin 6+DCM-1) [9 wt %]; the hole transport layer was a layer of TPD 15 nm thick; the light emitting layer was a DPVBi 30 nm thick; and the electron transport layer was a layer of Alq₃ with a film thickness of 20 nm. Subsequently, depositing lithium to a thickness of 1.5 nm, a cathode buffer layer was formed. In the process of depositing the hole-injective dye layer, the ratio of evaporation speed for CzPP to evaporation speed for the color conversion dye (sum of coumarin 6 and DCM-1) was 100:9. The ratio of evaporation speed for coumarin 6 to evaporation speed for DCM-1 was 1:2, and the molar ratio of coumarin 6 to DCM-1 was 3:7.

After that, a mask was positioned that gives a film of plural stripes extending in the transverse direction having a line width of 0.1 mm and a pitch of 0.11 mm. A CrB film was deposited through this mask to a thickness of 200 nm to obtain a reflective electrode.

Finally, the laminate having the reflective electrode formed thereon was taken out to a dry atmosphere (moisture concentration at most 1 ppm and oxygen concentration at most 1 ppm). The laminate was sealed off by bonding a sealing glass substrate with ultraviolet light-setting adhesive applied on the four sides thereof.

The sealed laminate was illuminated by dye-decomposing light with an intensity of 1 W/cm² from a carbon arc lamp (a white light source) located in the side of the transparent glass substrate through an optical system for obtaining parallel rays. In the region of the hole-injective dye layer corresponding to the red color filter layer, neither coumarin 6 nor DCM-1 decomposed, and a red color conversion layer was formed in this region. In the region of the hole-injective dye layer corresponding to the green color filter layer, coumarin 6 did not decompose and DCM-1 decomposed, and a green color conversion layer was formed in this region. In the region of the hole-injective dye layer corresponding to the blue color filter layer and the region without any color filter layer, both coumarin 6 and DCM-1 decomposed, and a transparent layer was formed in this region.

The two types of hole-injective color conversion layers in the organic EL display obtained by irradiation of dye-decomposing light were disposed corresponding to the color filter layers, and a fault such as distortion was not observed.

### Example 16

An organic EL display was manufactured in the same manner as in Example 15 except that a forward bias voltage of 10 V was applied on the organic EL layer, linearly and sequentially scanning the transparent electrode elements and the reflective electrode elements in the process of dye-decomposing light irradiation. In this example, the irradiation time of the dye-decomposing light was shortened by 30% as compared with in Example 15, demonstrating promotion of decomposition of the color conversion dye in the dye layer by the emission from the organic EL layer.

### Example 17

An organic EL display was manufactured in the same manner as in Example 16 except that the light emitting elements in the area corresponding to the red color filter layer was not lit in the process of the linear and sequential scanning of the transparent electrode elements and the reflective electrode elements. In this Example, also, as in Example 16, the irradiation time of the dye-decomposing light was shortened by 30% as compared with in Example 15, demonstrating promotion of decomposition of the color conversion dye in the dye layer by the emission from the organic EL layer.

### Example 18

An organic EL display was manufactured in the same manner as in Example 15 except that a reverse bias voltage of 20 V was applied on the organic EL layer, linearly and sequentially scanning the transparent electrode elements and the reflective electrode elements in the process of dye-decomposing light irradiation. No microscopic defect has been observed in the light emitting elements of the organic EL display obtained in this Example, demonstrating possibility of elimination of microscopic defects in the light emitting elements simultaneously with the formation of color conversion layers by irradiation of dye-decomposing light.

### Example 19

An organic EL display was manufactured in the same manner as in Example 16 except that each of the light emitting elements was subjected to ten times of application of alternate forward bias voltage (10 V) and reverse bias voltage (20 V) in the process of the linear and sequential scanning of the transparent electrode elements and the reflective electrode elements. In this Example, also, the irradiation time of the dye-decomposing light was shortened by 30% as compared with in Example 15, demonstrating promotion of decomposition of the color conversion dye in the dye layer by the emission from the organic EL layer. It has been further clarified that no microscopic defect has been observed in the light emitting elements of the organic EL display obtained in this Example, demonstrating possibility of elimination of microscopic defects in the light emitting elements simultaneously with the formation of color conversion layers by irradiation of dye-decomposing light.

### Example 20

An organic EL display was manufactured in the same manner as in Example 15 except that the laminate was heated to 65° C. in the process of irradiation of dye-decomposing light. In this Example, the irradiation time of the dye-decomposing light was shortened by 20% as compared with in Example 15, demonstrating promotion of decomposition of the color conversion dye in the dye layer by heating the laminate.

### Example 21

An organic EL display was manufactured in the same manner as in Example 15 except that the process of irradiation of dye-decomposing light was conducted in the two steps as described below.

On the laminate, a type of dye-decomposing light with an intensity of 1 W/cm² was irradiated from a carbon arc lamp (a white light source) located in the side of the transparent glass substrate through a band-pass filter that transmits light with wavelength in the range of 500 to 600 nm and an optical system for obtaining parallel rays. In the region of the dye layer over the green color filter layer and the blue color filter layer, and the region without any color filter layer, DCM-1 decomposed in this irradiation process.

Another type of dye-decomposing light with an intensity of 1 W/cm² was irradiated from a carbon arc lamp (a white light source) located in the side of the transparent glass substrate through a band-pass filter that transmits light with wavelength in the range of 450 to 510 nm and an optical system for obtaining parallel rays. In the region of the dye layer over the blue color filter layer, and the region without any color filter layer, coumarin 6 decomposed in this irradiation process.

By the two steps of irradiation of dye-decomposing light as described above, in the region of the dye layer over the red color filter layer, neither coumarin 6 nor DCM-1 decomposed, forming a red color conversion layer in this region. In the region of the dye layer over the green color filter layer, coumarin 6 did not decompose and DCM-1 decomposed, forming a green color conversion layer in this region. In the region of dye layer over the blue color filter layer and the region without any color filter layer, both coumarin 6 and DCM-1 decomposed, forming a transparent layer in this region.

### Example 22

A laminate having three types of color filter layers formed thereon was fabricated in the same manner as in Example 1. A solution of fluorescent color conversion dye was prepared by dissolving DCM-1 (0.6 parts by weight) and coumarin 6 (0.3 parts by weight) in a solvent of propylene-glycol monoethyl acetate (120 parts by weight). To this solution, 100 parts by weight of PMMA (poly(methyl methacrylate)) was added and dissolved to obtain a coating liquid. The coating liquid was applied on the laminate having the color filter layers formed thereon by means of a spin coating method. After heating and drying, a dye layer 7 μm thick containing the PMMA resin was formed. The molar ratio of coumarin 6 to DCM 1 was 3:7.

Then, the laminate was transferred into a facing target sputtering apparatus. A mask was positioned that gives a film of plural stripes extending in the longitudinal direction having a line width of 0.1 mm and a pitch of 0.11 mm, and by depositing ITO through this mask to a thickness of 200 nm, a transparent electrode was obtained.

Then, without breaking the vacuum, the laminate having the transparent electrode formed thereon was transferred into a vacuum evaporation apparatus, and sequentially deposited were four layers of a hole injection layer, a hole transport layer, a light emitting layer, and an electron transport layer, to obtain an organic EL layer. Each layer was deposited at an evaporation speed of 0.1 nm/s. The hole injection layer was a layer of CuPc 100 nm thick; the hole transport layer was a layer of α-NPD 10 nm thick; the light emitting layer was a DPVBi 30 nm thick; and the electron transport layer was a layer of Alq₃ with a film thickness of 20 nm. Subsequently, depositing lithium to a thickness of 1.5 nm, a cathode buffer layer was formed.

After that, a mask was positioned that gives a film of plural stripes extending in the transverse direction having a line width of 0.1 mm and a pitch of 0.11 mm. A CrB film was deposited through this mask to a thickness of 200 nm to obtain a reflective electrode.

Finally, the laminate having the reflective electrode formed thereon was taken out to a dry atmosphere (moisture concentration at most 1 ppm and oxygen concentration at most 1 ppm). The laminate was sealed off by bonding a sealing glass substrate with ultraviolet light-setting adhesive applied on the four sides thereof.

The sealed laminate was illuminated by dye-decomposing light with an intensity of 1 W/cm² from a carbon arc lamp (a white light source) located in the side of the transparent glass substrate through an optical system for obtaining parallel rays. In the region of the dye layer corresponding to the red color filter layer, neither coumarin 6 nor DCM-1 decomposed, and a red color conversion layer was formed in this region. In the region of the dye layer corresponding to the green color filter layer, coumarin 6 did not decompose and DCM-1 decomposed, and a green color conversion layer was formed in this region. In the region of the dye layer corresponding to the blue color filter layer and the region without any color filter layer, both coumarin 6 and DCM-1 decomposed, and a transparent layer was formed in this region.

Both of the two types of color conversion layers containing the PMMA resin in the organic EL display obtained by irradiation of dye-decomposing light were disposed corresponding to the color filter layers, and a fault such as distortion was not observed.

### Example 23

An organic EL display was manufactured in the same manner as in Example 22 except that a forward bias voltage of 10 V was applied on the organic EL layer, linearly and sequentially scanning the transparent electrode elements and the reflective electrode elements in the process of dye-decomposing light irradiation. In this example, the irradiation time of the dye-decomposing light was shortened by 30% as compared with in Example 22, demonstrating promotion of decomposition of the color conversion dye in the dye layer by the emission from the organic EL layer.

### Example 24

An organic EL display was manufactured in the same manner as in Example 23 except that the light emitting elements in the area corresponding to the red color filter layer was not lit in the process of the linear and sequential scanning of the transparent electrode elements and the reflective electrode elements. In this Example, also, as in Example 23, the irradiation time of the dye-decomposing light was shortened by 30% as compared with in Example 22, demonstrating promotion of decomposition of the color conversion dye in the dye layer by the emission from the organic EL layer.

### Example 25

An organic EL display was manufactured in the same manner as in Example 22 except that a reverse bias voltage of 20 V was applied on the organic EL layer, linearly and sequentially scanning the transparent electrode elements and the reflective electrode elements in the process of dye-decomposing light irradiation. No microscopic defect has been observed in the light emitting elements of the organic EL display obtained in this Example, demonstrating possibility of elimination of microscopic defects in the light emitting elements simultaneously with the formation of color conversion layers by irradiation of dye-decomposing light.

### Example 26

An organic EL display was manufactured in the same manner as in Example 23 except that each of the light emitting elements was subjected to ten times of application of alternate forward bias voltage (10 V) and reverse bias voltage (20 V) in the process of the linear and sequential scanning of the transparent electrode elements and the reflective electrode elements. In this Example, also, the irradiation time of the dye-decomposing light was shortened by 30% as compared with in Example 22, demonstrating promotion of decomposition of the color conversion dye in the dye layer by the emission from the organic EL layer. It has been further clarified that no microscopic defect has been observed in the light emitting elements of the organic EL display obtained in this Example, demonstrating possibility of elimination of microscopic defects in the light emitting elements simultaneously with the formation of color conversion layers by irradiation of dye-decomposing light.

### Example 27

An organic EL display was manufactured in the same manner as in Example 22 except that the laminate was heated to 65° C. in the process of irradiation of dye-decomposing light. In this Example, the irradiation time of the dye-decomposing light was shortened by 20% as compared with in Example 22, demonstrating promotion of decomposition of the color conversion dye in the dye layer by heating the laminate.

### Example 28

An organic EL display was manufactured in the same manner as in Example 22 except that the process of irradiation of dye-decomposing light was conducted in the two steps as described below.

On the laminate, a type of dye-decomposing light with an intensity of 1 W/cm² was irradiated from a carbon arc lamp (a white light source) located in the side of the transparent glass substrate through a band-pass filter that transmits light with wavelength in the range of 500 to 600 nm and an optical system for obtaining parallel rays. In the region of the dye layer over the green color filter layer and the blue color filter layer, and the region without any color filter layer, DCM-1 decomposed in this irradiation process.

Another type of dye-decomposing light with an intensity of 1 W/cm² was irradiated from a carbon arc lamp (a white light source) located in the side of the transparent glass substrate through a band-pass filter that transmits light with wavelength in the range of 450 to 510 nm and an optical system for obtaining parallel rays. In the region of the dye layer over the blue color filter layer, and the region without any color filter layer, coumarin 6 decomposed in this irradiation process.

By the two steps of irradiation of dye-decomposing light as described above, in the region of the dye layer over the red color filter layer, neither coumarin 6 nor DCM-1 decomposed, forming a red color conversion layer in this region. In the region of the dye layer over the green color filter layer, coumarin 6 did not decompose and DCM-1 decomposed, forming a green color conversion layer in this region. In the region of dye layer over the blue color filter layer and the region without any color filter layer, both coumarin 6 and DCM-1 decomposed, forming a transparent layer in this region.

### Example 29

Blue color filter material (Color Mosaic CB-7001, a product of FUJIFILM Electronic Materials Co., Ltd.) was applied on a transparent glass substrate 1 (Corning 1737 glass) by a spin coating method, and patterned by a photolithography method, to form a blue color filter layer 2c of plural strips extending in the longitudinal direction having a line width of 0.1 mm, a pitch of 0.33 mm (distance between two adjacent lines being 0.23 mm), and a film thickness of 2 μm.

On the substrate having the blue color filter layer formed thereon, a green color filter material (Color Mosaic CG-7001, a product of FUJIFILM Electronic Materials Co., Ltd.) was applied by a spin coating method, and patterned by a photolithography method, to form a green color filter layer 2b of plural stripes extending in the longitudinal direction having a line width of 0.1 mm, a pitch of 0.33 mm, and a film thickness of 2 μm.

Then, a red color filter material (Color Mosaic CR-7001, a product of FUJIFILM Electronic Materials Co., Ltd.) was applied by a spin coating method, and patterned by a photolithography method, to form a red color filter layer 2a of plural stripes extending in the longitudinal direction having a line width of 0.1 mm, a pitch of 0.33 mm, and a film thickness of 2 μm.

A glass substrate 71 was prepared preliminarily provided with switching elements 72 of TFTs and a planarizing insulator film 73 with openings for source electrodes of the TFTs. On the glass substrate 71, a silver layer 500 nm thick and an IZO layer 100 nm thick were deposited by a sputtering method using a mask to form a reflective electrode 13 consisting of plural electrode elements each connecting to a source electrode of each TFT in one-to-one correspondence. The electrode elements, each having dimensions of 0.32 mm in longitudinal direction×0.12 mm in transverse direction, were arranged in a matrix form with a gap of 0.01 mm in both longitudinal and transverse directions.

Applying a coating liquid for an insulation film, and patterning by a photolithography method, an insulation film 74 with a grid configuration was formed. The insulation film 74 was formed such that the edge region with a width of 0.01 mm of every electrode elements of the reflective electrode 13 is covered with a part of the insulation film.

Then, the laminate having the insulation film 74 formed thereon was set in a resistance heating vacuum evaporation apparatus, and sequentially deposited on the reflective electrode 13 were four layers of a hole injection layer, a hole transport layer, a light emitting layer, and an electron transport layer, to obtain an organic EL layer. The hole injection layer was a layer of CuPc 100 nm thick; the hole transport layer was a layer of α-NPD 10 nm thick; the light emitting layer was a DPVBi 30 nm thick; and the electron transport layer was a layer of Alq₃ with a film thickness of 20 nm. Subsequently, depositing Mg/Ag (weight ratio of 10:1) to a thickness of 10 nm, a cathode buffer layer was formed. Then, IZO 100 nm thick was deposited to form a single film of transparent electrode 11.

Over the whole surface of the transparent electrode 11, a dye layer 3 having a thickness of 200 nm was formed by co-evaporating CzPP: (coumarin 6+DCM-1) [9 wt %]. After that, a passivation layer 75 covering the structure including the dye layer and the lower layers was formed of SiN 1 μm thick to obtain a laminate consisting of a second substrate, an organic EL device, and a dye layer.

The thus obtained laminate consisting of a transparent substrate and color filter layers and the laminate consisting of a second substrate, an organic EL device, and a dye layer were transferred into a globe box controlled at a moisture concentration of at most 1 ppm and an oxygen concentration of at most 1 ppm; Around outer periphery of the laminate consisting of a transparent substrate and color filter layers, an adhesion layer 80 was formed by applying an ultraviolet light-setting adhesive (30Y-437, a product of Three Bond Co., Ltd.) containing dispersed beads having a diameter of 20 μm using a dispenser robot. Adjusting the positions of the color filter layers and the light emitting elements of the organic EL device, the two laminates, the laminate consisting of a transparent substrate and color filter layers and the laminate consisting of a second substrate, an organic EL device, and a dye layer, were combined together. On this assembly, ultraviolet light of 100 mW/cm² was irradiated for 30 sec using a UV lamp, to set the adhesion layer 80 and seal the outer periphery.

In the side of the transparent glass substrate of the obtained assembly, a carbon arc lamp (a white light source) and an optical system for obtaining parallel rays were arranged. And the assembly was illuminated by dye-decomposing light with an intensity of 1 W/cm² to form an organic EL display including color conversion layers. In the region of the dye layer 3 corresponding to the red color filter layer 2a, decomposition of neither coumarin 6 nor DCM-1 advanced, and a red color conversion layer 4a was formed in this region. In the region of the dye layer 3 corresponding to the green color filter layer 2b, coumarin 6 did not decompose and DCM-1 decomposed, and a green color conversion layer 4b was formed in this region. In the region of the dye layer 3 corresponding to the blue color filter layer 2c and the region without any color filter layer, both coumarin 6 and DCM-1 decomposed, and a transparent layer 5 was formed in this region.

The two types of color conversion layers 4a and 4b in the obtained organic EL display were disposed in the regions corresponding to the color filter layers 2a and 2b, respectively, and a fault such as distortion was not observed.

### Example 30

An organic EL display was manufactured in the same manner as in Example 29 except that a forward bias voltage of 10 V was applied on the organic EL layer to light every pixels in the process of dye-decomposing light irradiation. In this example, the irradiation time of the dye-decomposing light was shortened by 30% as compared with in Example 29, demonstrating promotion of decomposition of the color conversion dye in the dye layer by the emission from the organic EL layer.

### Example 31

An organic EL display was manufactured in the same manner as in Example 30 except that the light emitting elements in the area corresponding to the red color filter layer 2a was not lit. In this Example, also, as in Example 30, the irradiation time of the dye-decomposing light was shortened by 30% as compared with in Example 29, demonstrating promotion of decomposition of the color conversion dye in the dye layer by the emission from the organic EL layer.

### Example 32

An organic EL display was manufactured in the same manner as in Example 29 except that the laminate was heated to 65° C. in the process of irradiation of dye-decomposing light. In this Example, the irradiation time of the dye-decomposing light was shortened by 20% as compared with in Example 29, demonstrating promotion of decomposition of the color conversion dye in the dye layer by heating the laminate.

### Example 33

An organic EL display was manufactured in the same manner as in Example 29 except that the process of irradiation of dye-decomposing light was conducted in the two steps as described below.

On the laminate, a type of dye-decomposing light with an intensity of 1 W/cm² was irradiated from a carbon arc lamp (a white light source) located in the side of the transparent substrate 1 through a band-pass filter that transmits light with wavelength in the range of 500 to 600 nm and an optical system for obtaining parallel rays. In the regions of the dye layer 3 corresponding to the green color filter layer 2b and the blue color filter layer 2c, and the region without any color filter layer, DCM-1 decomposed in this irradiation process.

Another type of dye-decomposing light with an intensity of 1 W/cm² was irradiated from a carbon arc lamp (a white light source) located in the side of the transparent substrate 1 through a band-pass filter that transmits light with wavelength in the range of 450 to 510 nm and an optical system for obtaining parallel rays. In the region of the dye layer 3 corresponding to the blue color filter layer 2c, and the region without any color filter layer, coumarin 6 decomposed in this irradiation process.

By the two steps of irradiation of dye-decomposing light as described above, in the region of the dye layer 3 corresponding to the red color filter layer 2a, decomposition of neither coumarin 6 nor DCM-1 advanced, forming a red color conversion layer 4a in this region. In the region of the dye layer 3 corresponding to the green color filter layer 2b, coumarin 6 did not decompose and DCM-1 decomposed, forming a green color conversion layer 4b in this region. In the region of dye layer 3 corresponding to the blue color filter layer 2c and the region without any color filter layer, both coumarin 6 and DCM-1 decomposed, forming a transparent layer 5 in this region.

It will be appreciated by those skilled in the art that the invention may be practiced otherwise than as specifically disclosed herein without departing from the scope thereof.

What is claimed is:

1. A method of manufacturing an organic EL display comprising steps of:
forming n types of color filter layers on a transparent substrate;
forming a dye layer containing (n−1) types of color conversion dyes on the n types of color filter layers by means of a dry process;
forming an organic EL device having a plurality of independent light emitting elements on the dye layer, the organic EL device including at least a first electrode, a second electrode, and an organic EL layer disposed between the first and second electrodes; and
exposing the dye layer to dye-decomposing light through the transparent substrate and the color filter layers to form an m-th type color conversion layer at a position corresponding to an m-th type color filter layer; wherein
n represents an integer from 2 to 6;
m represents an integer from 1 to (n−1);
each of the n types of color filter layers transmits light in a distinct wavelength region different from each other;
an m-th type color conversion dye is decomposed by light that is cut by the m-th type color filter layer; and
the m-th type color conversion layer emits light that is transmitted by the m-th type color filter layer, after wavelength distribution conversion.

2. The method of manufacturing an organic EL display according to claim 1, wherein a bias voltage is applied to the plurality of independent light emitting elements in the step of exposing to the dye-decomposing light.

3. The method of manufacturing an organic EL display according to claim 2, wherein a forward bias voltage is applied to the plurality of independent light emitting elements.

4. The method of manufacturing an organic EL display according to claim 2, wherein the forward bias voltage is applied only to selected light emitting elements of the plurality of independent light emitting elements.

5. The method of manufacturing an organic EL display according to claim 1, wherein the step of exposing to dye-decomposing light is conducted plural times and a wavelength component that decomposes the m-th type of color conversion dye is included in dye-decomposing light used at least one of the plural times.

6. The method of manufacturing an organic EL display according to claim 2 further comprising a step of monitoring an emission spectrum from the organic EL display during application of a forward bias voltage to the plurality of independent light emitting elements and controlling a quantity of dye-decomposing light according to the emission spectrum.

7. The method of manufacturing an organic EL display according to claim 2, wherein a reverse bias voltage is applied to the plurality of independent light emitting elements.

8. The method of manufacturing an organic EL display according to claim 2, wherein a forward bias voltage and a reverse bias voltage are alternately applied to the plurality of independent light emitting elements.

9. The method of manufacturing an organic EL display according to claim 1, wherein the transparent substrate is heated in the step of exposing to the dye-decomposing light.

10. A method of manufacturing an organic EL display comprising steps of:
forming n types of color filter layers on a transparent substrate;
forming an organic EL device having a plurality of independent light emitting elements on the n types of color filter layers, the organic EL device including at least a first electrode, a second electrode, and an organic EL layer disposed between the first and second electrodes;
forming a dye layer containing (n−1) types of color conversion dyes on the organic EL device by means of a dry process;
forming a reflective layer on the dye layer; and
exposing the dye layer to dye-decomposing light through the transparent substrate and the color filter layers to form an m-th type color conversion layer at a position corresponding to an m-th type color filter layer; wherein
n represents an integer from 2 to 6;
m represents an integer from 1 to (n−1);
each of the n types of color filter layers transmits light in a distinct wavelength region different from each other;
an m-th type color conversion dye is decomposed by light that is cut by the m-th type color filter layer; and
the m-th type color conversion layer emits light that is transmitted by the m-th type color filter layer, after wavelength distribution conversion.

11. The method of manufacturing an organic EL display according to claim 10, wherein a bias voltage is applied to the plurality of independent light emitting elements in the step of exposing to the dye-decomposing light.

12. The method of manufacturing an organic EL display according to claim 11, wherein a forward bias voltage is applied to the plurality of independent light emitting elements.

13. The method of manufacturing an organic EL display according to claim 11, wherein a forward bias voltage is applied only to selected light emitting elements of the plurality of independent light emitting elements.

14. The method of manufacturing an organic EL display according to claim 10, wherein the step of exposing to dye-decomposing light is conducted plural times and a wavelength component that decomposes the m-th type of color conversion dye is included in dye-decomposing light used at least one of the plural times.

15. The method of manufacturing an organic EL display according to claim 11 further comprising a step of monitoring an emission spectrum from the organic EL display during application of a forward bias voltage to the plurality of independent light emitting elements and controlling a quantity of dye-decomposing light according to the emission spectrum.

16. The method of manufacturing an organic EL display according to claim 11, wherein a reverse bias voltage is applied to the plurality of independent light emitting elements.

17. The method of manufacturing an organic EL display according to claim 11, wherein a forward bias voltage and a reverse bias voltage are alternately applied to the plurality of independent light emitting elements.

18. The method of manufacturing an organic EL display according to claim 10, wherein the transparent substrate is heated in the step of exposing to the dye-decomposing light.

19. A method of manufacturing an organic EL display comprising steps of:
forming n types of color filter layers on a transparent substrate;
forming an organic EL device having a plurality of independent light emitting elements on the n types of color filter layers by means of a dry process, the organic EL device including at least a first electrode, a second electrode, and an organic EL layer including at least an organic light emitting layer and a carrier-transporting dye layer disposed between the first and second electrodes, the carrier-transporting dye layer including at least (n−1) types of color conversion dyes; and
exposing the carrier-transporting dye layer to dye-decomposing light through the transparent substrate and the color filter layers to form an m-th type carrier-transporting color conversion layer at a position corresponding to an m-th type color filter layer; wherein
n represents an integer from 2 to 6;
m represents an integer from 1 to (n−1);
each of the n types of color filter layers transmits light in a distinct wavelength region different from each other;
an m-th type color conversion dye is decomposed by light that is cut by the m-th type color filter layer; and
the m-th type carrier-transporting color conversion layer emits light that is transmitted by the m-th type color filter layer, after wavelength distribution conversion.

20. The method of manufacturing an organic EL display according to claim 19, wherein a bias voltage is applied to the plurality of independent light emitting elements in the step of exposing to the dye-decomposing light.

21. The method of manufacturing an organic EL display according to claim 20, wherein a forward bias voltage is applied to the plurality of independent light emitting elements.

22. The method of manufacturing an organic EL display according to claim 20, wherein a forward bias voltage is applied only to selected light emitting elements of the plurality of independent light emitting elements.

23. The method of manufacturing an organic EL display according to claim 19, wherein the step of exposing to dye-decomposing light is conducted plural times and a wavelength component that decomposes the m-th type of color conversion dye is included in dye-decomposing light used at least one of the plural times.

24. The method of manufacturing an organic EL display according to claim 20 further comprising a step of monitoring an emission spectrum from the organic EL display during application of a forward bias voltage to the plurality of independent light emitting elements and controlling a quantity of dye-decomposing light according to the emission spectrum.

25. The method of manufacturing an organic EL display according to claim 20, wherein a reverse bias voltage is applied to the plurality of independent light emitting elements.

26. The method of manufacturing an organic EL display according to claim 20, wherein a forward bias voltage and a reverse bias voltage are alternately applied to the plurality of independent light emitting elements.

27. The method of manufacturing an organic EL display according to claim 19, wherein the transparent substrate is heated in the step of exposing to the dye-decomposing light.

28. A method of manufacturing an organic EL display comprising steps of:
forming n types of color filter layers on a transparent substrate;
forming a dye layer containing (n−1) types of color conversion dyes dispersed in a resin on the n types of color filter layers;
forming an organic EL device having a plurality of independent light emitting elements on the dye layer, the organic EL device including at least a first electrode, a second electrode, and an organic EL layer disposed between the first and second electrodes; and
exposing the dye layer to dye-decomposing light through the transparent substrate and the color filter layers to form an m-th type color conversion layer at a position corresponding to an m-th type color filter layer; wherein
n represents an integer from 2 to 6;
m represents an integer from 1 to (n−1);
each of the n types of color filter layers transmits light in a distinct wavelength region different from each other;
an m-th type color conversion dye is decomposed by light that is cut by the m-th type color filter layer; and
the m-th type color conversion layer emits light that is transmitted by the m-th type color filter layer, after wavelength distribution conversion.

29. The method of manufacturing an organic EL display according to claim 28, wherein a bias voltage is applied to the plurality of independent light emitting elements in the step of exposing to the dye-decomposing light.

30. The method of manufacturing an organic EL display according to claim 29, wherein a forward bias voltage is applied to the plurality of independent light emitting elements.

31. The method of manufacturing an organic EL display according to claim 29, wherein a forward bias voltage is applied only to selected light emitting elements of the plurality of independent light emitting elements.

32. The method of manufacturing an organic EL display according to claim 28, wherein the step of exposing to dye-decomposing light is conducted plural times and a wavelength component that decomposes the m-th type of color conversion dye is included in dye-decomposing light used at least one of the plural times.

33. The method of manufacturing an organic EL display according to claim 29 further comprising a step of monitoring an emission spectrum from the organic EL display during application of a forward bias voltage to the plurality of independent light emitting elements and controlling a quantity of dye-decomposing light according to the emission spectrum.

34. The method of manufacturing an organic EL display according to claim 29, wherein a reverse bias voltage is applied to the plurality of independent light emitting elements.

35. The method of manufacturing an organic EL display according to claim 29, wherein a forward bias voltage and a reverse bias voltage are alternately applied to the plurality of independent light emitting elements.

36. The method of manufacturing an organic EL display according to claim 28, wherein the transparent substrate is heated in the step of exposing to the dye-decomposing light.

37. A method of manufacturing an organic EL display comprising steps of:
forming n types of color filter layers on a transparent substrate;
forming an organic EL device having a plurality of independent light emitting elements on a second substrate, the organic EL device including at least a first electrode, a second electrode, and an organic EL layer disposed between the first and second electrodes;
forming a dye layer containing (n−1) types of color conversion dyes on the organic EL device;
combining the transparent substrate and the second substrate together such that the color filter layers are opposing the dye layer; and
exposing the dye layer to dye-decomposing light through the transparent substrate and the color filter layers to form an m-th type color conversion layer at a position corresponding to an m-th type color filter layer; wherein
n represents an integer from 2 to 6;
m represents an integer from 1 to (n−1);
each of the n types of color filter layers transmits light in a distinct wavelength region different from each other;
an m-th type color conversion dye is decomposed by light that is cut by the m-th type color filter layer; and
the m-th type color conversion layer emits light that is transmitted by the m-th type color filter layer, after wavelength distribution conversion.

38. The method of manufacturing an organic EL display according to claim 37, wherein a bias voltage is applied to the plurality of independent light emitting elements in the step of exposing to the dye-decomposing light.

39. The method of manufacturing an organic EL display according to claim 38, wherein a forward bias voltage is applied to the plurality of independent light emitting elements.

40. The method of manufacturing an organic EL display according to claim 38, wherein a forward bias voltage is applied only to selected light emitting elements of the plurality of independent light emitting elements.

41. The method of manufacturing an organic EL display according to claim 37, wherein the step of exposing to dye-decomposing light is conducted plural times and a wavelength component that decomposes the m-th type of color conversion dye is included in dye-decomposing light used at least one of the plural times.

42. The method of manufacturing an organic EL display according to claim 38 further comprising a step of monitoring an emission spectrum from the organic EL display during application of a forward bias voltage to the plurality of independent light emitting elements and controlling a quantity of dye-decomposing light according to the emission spectrum.

43. The method of manufacturing an organic EL display according to claim 37, wherein the transparent substrate is heated in the step of exposing to the dye-decomposing light.
